(19) United States
(12) Patent Application Publication
(10) Pub. No.: US 2026/0143951 A1
(43) Pub. Date: May 21, 2026

(54) ELECTRONIC DEVICE AND METHOD OF MANUFACTURING THE ELECTRONIC DEVICE

(71) Applicant: Samsung Display Co., Ltd., Yongin-si (KR)

(72) Inventors: KI NYENG KANG, Yongin-si (KR); Chanju PARK, Yongin-si (KR); EON SEOK OH, Yongin-si (KR); SUNGEUN LEE, Yongin-si (KR); KEUNKYU SONG, Yongin-si (KR)

(21) Appl. No.: 19/274,960

(22) Filed: Jul. 21, 2025

(30) Foreign Application Priority Data
Nov. 21, 2024 (KR) 10-2024-0167395

(51) Int. Cl. H10K 59/80; G06F 3/044; H10K 59/12; H10K 59/124; H10K 59/40; H10K 59/88; H10K 102/00

(52) U.S. Cl. CPC H10K 59/873; G06F 3/044; H10K 59/1201; H10K 59/124; H10K 59/40; H10K 59/88; G06F 2203/04106; H10K 2102/351

(57) ABSTRACT

An electronic device includes a base substrate including a display area and a non-display area, a circuit layer on the base substrate, a light emitting element layer on the circuit layer, and an encapsulation layer. The light emitting element includes a first electrode on the circuit layer, a functional layer, and a second electrode. The circuit layer includes a conductive pattern, and a dummy pattern which is spaced further apart from the display area compared to the conductive pattern. The dummy pattern includes the same material as the functional layer or the second electrode. The encapsulation layer includes a first inorganic layer which covers the light emitting element and the dummy pattern, and a second inorganic layer, a portion of which is on the first inorganic layer. The second inorganic layer includes a first portion overlapping the first inorganic layer, and a second portion non-overlapping the first inorganic layer.

This application claims priority to Korean Patent Application No. 10-2024-0167395, filed on Nov. 21, 2024, and all the benefits accruing therefrom under 35 U.S.C. § 119, the content of which in its entirety is herein incorporated by reference.

### BACKGROUND

### Field

The present disclosure herein relates to an electronic device and a method for manufacturing the electronic device, and more particularly, to an electronic device in which a bezel area is reduced and durability is improved, and a method for manufacturing the electronic device.

### Description of the Related Art

In general, electronic equipment such as, for example, smartphones, digital cameras, notebook computers, navigation devices, and smart televisions, which provide images for users, include electronic devices for displaying the images. An electronic device generates an image and provides a user with the generated image through a display screen. The electronic device includes a plurality of pixels for generating the image and a plurality of lines connected to the pixels.

Recently, in order to provide a user with a display area having a larger surface area, an electronic device for minimizing a bezel area in which a pixel is not disposed is being developed. In some aspects, technologies for securing durability of this electronic device are desired.

### SUMMARY

The present disclosure provides an electronic device with a minimized unnecessary non-display area and improved durability.

The present disclosure also provides a method for manufacturing an electronic device. The method is capable of improving durability of a display panel through a simplified process.

An embodiment of the inventive concept provides an electronic device including a base substrate including a display area and a non-display area adjacent to the display area, a circuit layer disposed on the base substrate, a light emitting element layer disposed on the circuit layer and including a light emitting element, and an encapsulation layer which covers the light emitting element. The light emitting element includes a first electrode disposed on the circuit layer, a functional layer disposed on the first electrode and including at least an emission layer, and a second electrode disposed on the functional layer. The circuit layer includes a conductive pattern which is disposed on the non-display area, and a dummy pattern which is spaced further apart from the display area compared to the conductive pattern. The dummy pattern includes the same material as at least a portion of the functional layer or the second electrode. The encapsulation layer includes a first inorganic layer which covers the light emitting element and the dummy pattern, and a second inorganic layer, wherein a portion of the second inorganic layer is disposed on the first inorganic layer. The second inorganic layer includes a first portion overlapping the first inorganic layer, and a second portion non-overlapping the first inorganic layer and disposed in the non-display area.

In an embodiment, the second portion may not overlap the dummy pattern.

In an embodiment, the second inorganic layer may include at least one of silicon oxide, silicon nitride, silicon oxynitride, titanium oxide, or aluminum oxide.

In an embodiment, a distance from an end of the dummy pattern to an end of the base substrate may be about 3 micrometers to about 100 micrometers.

In an embodiment, the conductive pattern may include a first layer, a second layer, and a third layer which are stacked in sequence. The first layer and the third layer may include the same metal, and the second layer may include a different metal from each of the first layer and the third layer.

In an embodiment, the first inorganic layer may include a first cover portion disposed on the conductive pattern, a second cover portion which covers a side surface of conductive pattern, and a third cover portion which covers an upper portion of the dummy pattern.

In an embodiment, the first portion of the second inorganic layer may include a (1-1)-th portion disposed on the first cover portion, a (1-2)-th portion which covers a side surface of the second cover portion, and a (1-3)-th portion disposed on the third cover portion. The (1-3)-th portion and the second portion may be connected and have a shape of one body.

In an embodiment, the dummy pattern may include a first dummy pattern including the same material as at least the portion of the functional layer, and a second dummy pattern disposed on the first dummy pattern and including the same material as the second electrode.

In an embodiment, a sum of a thickness of the first inorganic layer and a thickness of the first portion may be greater than a thickness of the second portion.

In an embodiment, the first portion of the second inorganic layer may be directly disposed on the first inorganic layer.

In an embodiment, the encapsulation layer may further include an organic encapsulation layer disposed on the first portion of the second inorganic layer, and an upper inorganic encapsulation layer disposed on the organic encapsulation layer.

In an embodiment, the circuit layer may further include a lower insulating layer configured to provide a base surface on which the conductive pattern is disposed. The second portion may be in contact with a top surface of the lower insulating layer.

In an embodiment, the lower insulating layer includes at least one of silicon oxide, silicon nitride, silicon oxynitride, titanium oxide, or aluminum oxide. An interface may be provided between the second portion and the lower insulating layer.

In an embodiment, the light emitting element may further include a capping layer disposed on the second electrode. The dummy pattern may include a first dummy pattern including the same material as at least a portion of the functional layer, a second dummy pattern disposed on the first dummy pattern and including the same material as the second electrode, and a third dummy pattern disposed on the second dummy pattern and including the same material as the capping layer.

In an embodiment, an end of the dummy pattern and an end of the first inorganic layer may define an aligned surface.

In an embodiment of the inventive concept, an electronic device includes a base substrate including a first area and a second area adjacent to the first area, a circuit layer disposed on the base substrate, a light emitting element layer disposed on the circuit layer and including a light emitting element, and an encapsulation layer which covers the light emitting element. The light emitting element includes a first electrode disposed on the circuit layer, a functional layer disposed on the first electrode and including at least an emission layer, and a second electrode disposed on the functional layer. The circuit layer includes a conductive pattern disposed in the first area, and a dummy pattern disposed in the second area and spaced apart from the first area with the conductive pattern disposed between the dummy pattern and the first area, and the dummy pattern includes the same material as at least a portion of the functional layer or the second electrode. The encapsulation layer includes a lower inorganic encapsulation layer, wherein a portion of the lower inorganic encapsulation layer covers the light emitting element and the dummy pattern, and the lower inorganic encapsulation layer includes a first portion overlapping the dummy pattern and a second portion non-overlapping the dummy pattern and in the second area, wherein a thickness of the first portion is greater than a thickness of the second portion.

In an embodiment of the inventive concept, a method for manufacturing an electronic device includes preparing a base substrate including a display area and a non-display area adjacent to the display area, forming a circuit layer on the base substrate, forming, on the circuit layer, a light emitting element layer including a light emitting element, and forming an encapsulation layer on the light emitting element layer. The light emitting element includes a first electrode disposed on the circuit layer, a functional layer disposed on the first electrode and including at least an emission layer, and a second electrode disposed on the functional layer. The circuit layer includes a lower insulating layer, a conductive pattern overlapping the non-display area and disposed on the lower insulating layer, and a dummy pattern which is disposed on the lower insulating layer and spaced further apart from the display area compared to the conductive pattern, and the dummy pattern includes the same material as at least a portion of the functional layer or the second electrode. The forming of the encapsulation layer includes forming a preliminary first inorganic layer which covers the conductive pattern and the dummy pattern, etching a portion of the preliminary first inorganic layer wherein etching the portion of the preliminary first inorganic layer forms the first inorganic layer, and forming a second inorganic layer on the first inorganic layer. In the etching of the portion of the preliminary first inorganic layer, a portion of a top surface of the lower insulating layer is exposed, and the second inorganic layer is in contact with the exposed portion of the top surface of the lower insulating layer.

In an embodiment, in the etching of the portion of the preliminary first inorganic layer, a portion of the dummy pattern may be etched together.

In an embodiment, the second inorganic layer may include a first portion in contact with a top surface of the first inorganic layer, and a second portion in contact with the exposed portion of the top surface of the lower insulating layer.

In an embodiment, an end of the first inorganic layer and an end of the dummy pattern may be aligned with each other after the etching of the portion of the preliminary first inorganic layer.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a perspective view of an electronic device according to an embodiment of the inventive concept;

FIG. 1B is a block diagram of an electronic device according to an embodiment of the inventive concept;

FIG. 2 is a cross-sectional view of an electronic device according to an embodiment of the inventive concept;

FIG. 3 is a cross-sectional view of a display panel according to an embodiment of the inventive concept;

FIG. 4A is a block diagram of a display module according to an embodiment of the inventive concept;

FIG. 4B is an equivalent circuit diagram of one of pixels according to an embodiment of the inventive concept;

FIG. 5 is a plan view of a display module according to an embodiment of the inventive concept;

FIG. 6A is a cross-sectional view of a portion of a display panel according to an embodiment of the inventive concept;

FIG. 6B is an enlarged cross-sectional view of a portion of a display panel according to an embodiment of the inventive concept;

FIG. 7 is a plan view of pixel units according to an embodiment of the inventive concept;

FIG. 8A is a cross-sectional view of a portion of a display panel according to an embodiment of the inventive concept;

FIG. 8B is an enlarged cross-sectional view of a portion of a display panel according to an embodiment of the inventive concept;

FIG. 9 is a flowchart of a method for manufacturing an electronic device according to an embodiment of the inventive concept; and

FIGS. 10A to 10D are enlarged cross-sectional views illustrating some steps of a method for manufacturing an electronic device according to an embodiment of the inventive concept.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

As used herein, “being directly disposed” may mean that there is no additional layer, film, region, plate or the like between a part such as a layer, film, region, plate or the like and another part. For instance, “being directly disposed” may mean that two layers or two members are disposed with no additional member such as an adhesive member.

Like reference symbols refer to like elements throughout. In the drawings, the thickness, ratio, and size of the elements are exaggerated for effectively describing the technical contents. The term “and/or” includes one or more combinations which may be defined by relevant elements.

It will be understood that, although the terms “first”, “second”, and the like may be used herein to describe various elements, the elements are not to be limited by these terms. These terms are used to distinguish one element from another element. For instance, a first element, component, region, layer or section discussed below could be termed a second element, component, region, layer or section without departing from the scope of the inventive concept. Similarly, a second element, component, region, layer or section could be termed a first element, component, region, layer or section. In this specification, the singular expressions “a”, “an” and “the” are intended to include the plural forms as well, unless the context clearly indicates otherwise.

In some aspects, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described with reference to the accompanying drawings.

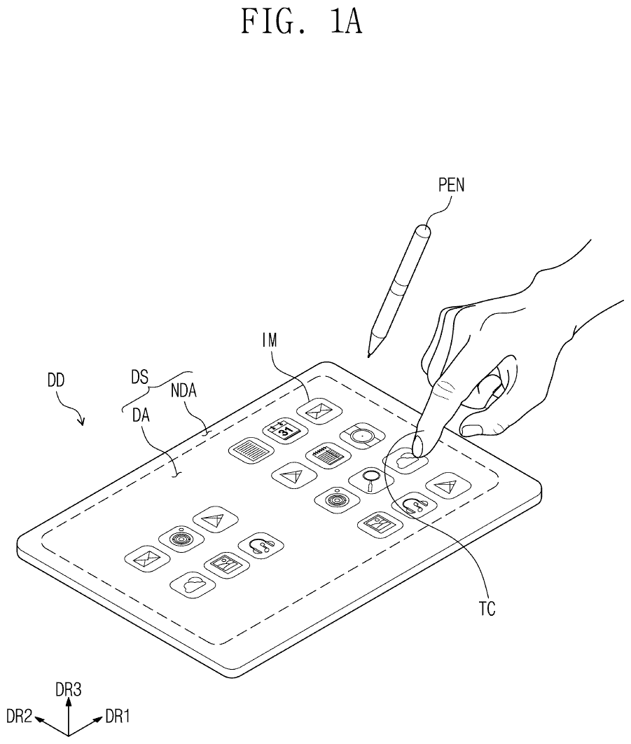

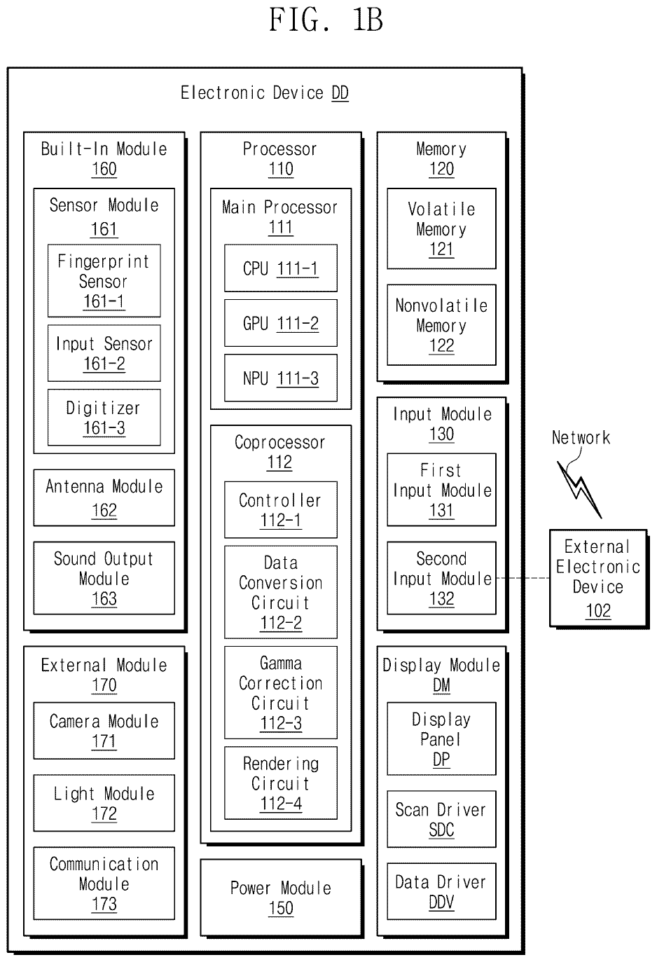

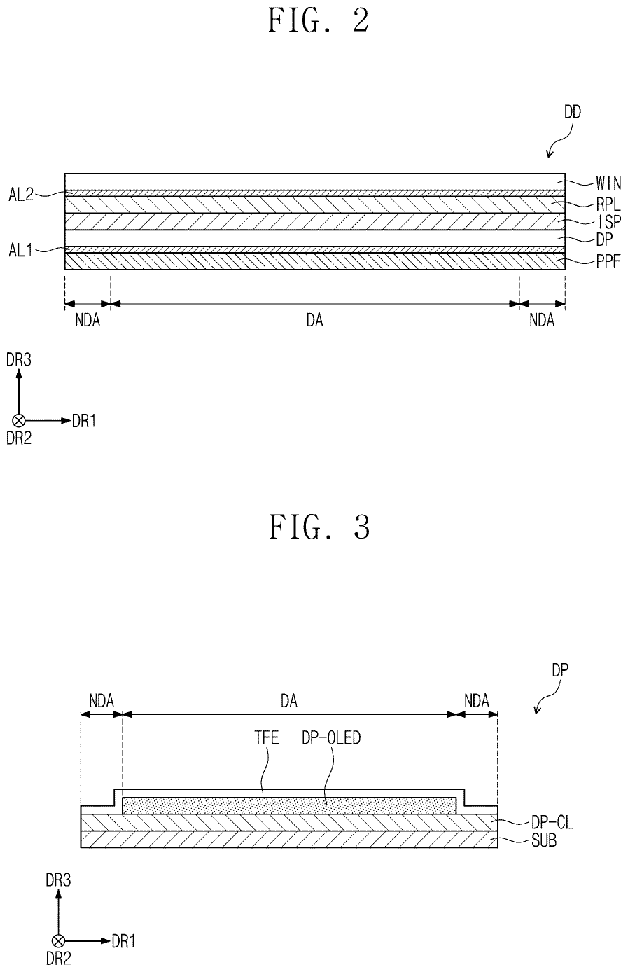

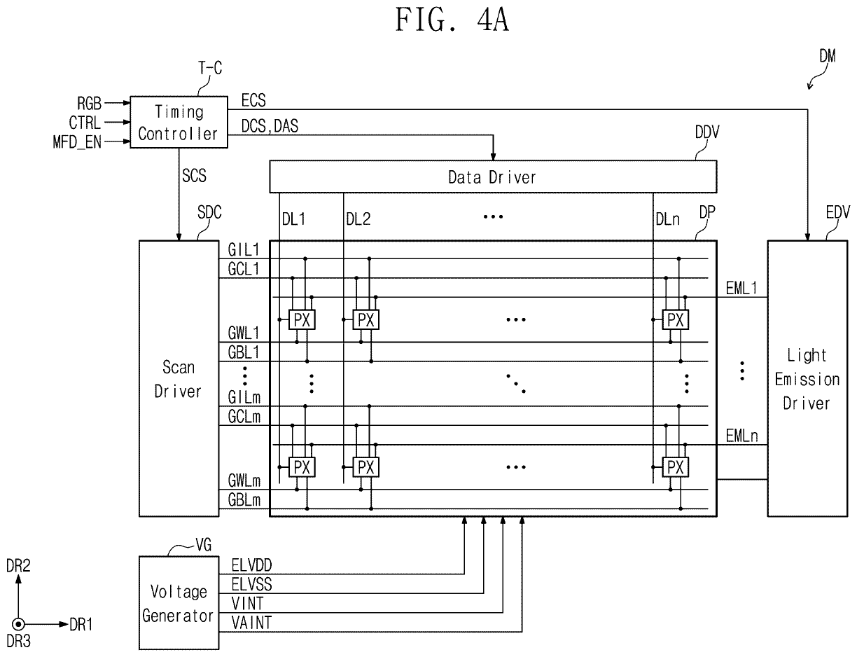

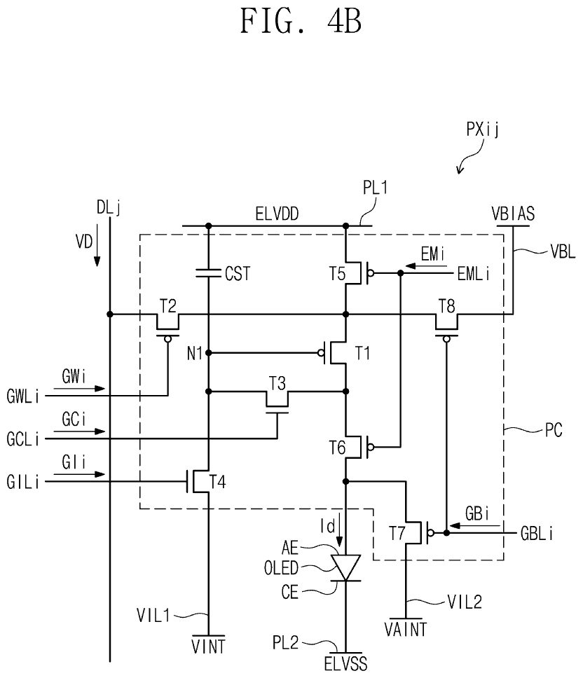

FIG. 1A is a perspective view of an electronic device according to an embodiment of the inventive concept. FIG. 1B is a block diagram of an electronic device according to an embodiment of the inventive concept. FIG. 2 is a cross-sectional view of an electronic device according to an embodiment of the inventive concept. FIG. 3 is a cross-sectional view of a display panel according to an embodiment of the inventive concept. FIG. 4A is a block diagram of a display module according to an embodiment of the inventive concept. FIG. 4B is an equivalent circuit diagram of one of pixels illustrated in FIG. 4A.

Referring to FIG. 1A, an electronic device DD according to an embodiment of the inventive concept may have long sides extending to be parallel to a first direction DR1 and short sides extending to be parallel to a second direction DR2 crossing the first direction DR1. Corners of the electronic device DD, which connect the long sides and the short sides, may have curve shapes. The corners of the electronic device DD, which have curve shapes, may be defined as round corners. This shape of the electronic device DD may be defined as a round corner rectangle. However, this is just one example of the shape of the electronic device DD, and the shape of the electronic device DD is not limited to the round corner rectangle.

Hereinafter, a direction substantially perpendicularly crossing a plane defined by the first direction DR1 and the second direction DR2 is defined as a third direction DR3. In some aspects, in the present disclosure, the meaning of when viewed on a plane is defined as being in a state when viewed in the third direction DR3.

A front surface of the electronic device DD may be defined as a display surface DS, and may have a plane defined by the first direction DR1 and the second direction DR2. Images IM generated in the electronic device DD may be provided for a user through the display surface DS.

The display surface DS may include a display area DA and a non-display area NDA around the display area DA. The display area DA may display an image, and the non-display area NDA may not display an image. The non-display area NDA may surround the display area DA, and define an edge of the electronic device DD, which is printed in a certain color.

The display area DA may have a round corner rectangular shape according to the shape of the electronic device DD. For example, the display area DA may include sides of a rectangle extending in the first direction DR1 and the second direction DR2, and rounded corners which connect the sides. The sides, which extend in the first direction DR1, of four sides may be defined as long sides, and the sides, which extend in the second direction DR2, of the four sides may be defined as short sides.

The electronic device DD may detect inputs applied from the outside of the electronic device DD. For example, the electronic device DD may detect a first input by a touch pen PEN and a second input by a touch TC. The touch pen PEN may be defined as an input device.

The touch pen PEN may be an active pen which outputs a signal. The second input by the touch TC may include various types of external inputs such as, for example, part of a user's body, light, heat, or pressure.

The electronic device DD and the touch pen PEN may bidirectionally communicate with each other. The electronic device DD may provide an uplink signal to the touch pen PEN. For example, the uplink signal may include panel information and information on a protocol version or the like, but is not particularly limited thereto.

The touch pen PEN may provide a downlink signal to the electronic device DD. The downlink signal may include a synchronization signal or state information of the touch pen PEN. For example, the downlink signal may include information on a coordinate of the touch pen PEN, information on a battery of the touch pen PEN, information on tilting of the touch pen PEN, and/or various information stored in the touch pen PEN, but is not particularly limited thereto.

The electronic device DD may be used for large-sized electronic devices such as, for example, televisions, monitors, or outdoor billboards. In some aspects, the electronic device DD may be used for a small and medium-sized electronic devices such as, for example, personal computers, notebook computers, personal digital assistants, vehicle navigation devices, game consoles, smartphones, tablet computers, or cameras. These are just provided as examples, and the electronic device DD may be used for other electronic devices unless departing from the inventive concept.

FIG. 1B illustrates a block diagram of an electronic device DD according to an embodiment. Referring to FIG. 1B, the electronic device DD outputs various information through a display module DM in an operating system. In an example in which a processor 110 executes an application stored in a memory 120, the display device DM provides application information for a user through a display panel DP.

The processor 110 obtains an external input through an input module 130 or a sensor module 161, and executes an application corresponding to the external input. In an example in which the user selects a camera icon displayed on the display panel DP, the processor 110 obtains a user input through an input sensor 161-2 and activates a camera module 171. The processor 110 transmits, to the display module DM, image data corresponding to a photographing image obtained through the camera module 171. The display module DM may display an image corresponding to the photographing image through the display panel DP.

As another example, when individual information authentication is performed in the display device DM, a fingerprint sensor 161-1 obtains fingerprint information input as input data. The processor 110 compares the input data obtained through the fingerprint sensor 161-1 with authentication data stored in the memory 120, and executes an application according to a result of the comparison. The display module DM may display, through the display panel DP, information executed according to a logic of the application.

As still another example, when a music streaming icon displayed on the display module DM is selected, the processor 110 obtains a user input through the input sensor 161-2 and activates a music streaming application stored in the memory 120. In an example in which a music play command is input to the music streaming application, the processor 110 activates a sound output module 163 and provides the user with sound information corresponding to the music play command.

In the above, the operations of the electronic device DD are described in brief. Hereinafter, components of the electronic device DD will be described in detail. Among the components of the electronic device DD to be described later, some components may be integrally provided as one component, and one component may be divided into two or more components.

Referring to FIG. 1B, the electronic device DD may communicate with an external electronic device 102 over a network (e.g., a short-range wireless communication network or a long-range wireless communication network). According to an embodiment, the electronic device DD may include the processor 110, the memory 120, the input module 130, the display device DM, a power module 150, a built-in module 160, and an external module 170. According to an embodiment, in the electronic device DD, at least one of the foregoing components may be omitted, or one or more other components may be added. According to an embodiment, some components (e.g., the sensor module 161, an antenna module 162, or the sound output module 163) of the foregoing components may be integrated into another component (e.g., the display module DM).

The processor 110 may execute software to control at least one other component (e.g., a hardware or software component) of the electronic device DD connected to the processor 110, and may perform various data processing or computation. According to an embodiment, as at least a part of the data processing or computation, the processor 110 may store a command or data received from other component (e.g., the input module 130, the sensor module 161, or a communication module 173) in a volatile memory 121, process the command or data stored in the volatile memory 121, and store the resulting data in a nonvolatile memory 122.

The processor 110 may include a main processor 111 and a coprocessor 112. The main processor 111 may include at least one of a central processing unit (CPU) 111-1 or an application processor (AP). The main processor 111 may also include at least one of a graphic processing unit (GPU) 111-2, a communication processor (CP), or an image signal processor (ISP). The main processor 111 may further include a neural processing unit (NPU) 111-3. The neural processing unit may be a processor specialized for processing of an artificial intelligence model, and the artificial intelligence model may be created through machine learning. The artificial intelligence model may include a plurality of artificial neural network layers. The artificial neural network may include one of deep neural network (DNN), convolutional neural network (CNN), recurrent neural network (RNN), restricted boltzmann machine (RBM), deep belief network (DBN), bidirectional recurrent deep neural network (BRDNN), deep Q-networks, or a combination of two or more of the foregoing networks, but is not limited to the foregoing examples. In some aspects or alternatively, the artificial intelligence model may include a software structure in addition to a hardware structure. At least two of the foregoing processing units and processors may be implemented as one integrated component (e.g., a single chip), or the foregoing processing units and processors may be implemented as independent components (e.g., a plurality of chips).

The coprocessor 112 may include a controller 112-1. The controller 112-1 may include an interface conversion circuit and a timing control circuit. The controller 112-1 receives an image signal from the main processor 111 and outputs image data obtained by converting a data format of the image signal to a format suitable for the specification of an interface with the display module DM. The controller 112-1 may output various control signals supportive of driving the display module DM.

The coprocessor 112 may further include a data conversion circuit 112-2, a gamma correction circuit 112-3, a rendering circuit 112-4, or the like. The data conversion circuit 112-2 may receive image data from the controller 112-1, and compensate for the image data such that an image is displayed with a desired luminance according to a characteristic of the electronic device DD or user settings, or convert the image data to reduce power consumption or compensate for image-sticking. The gamma correction circuit 112-3 may convert image data, a gamma reference voltage, or the like such that an image displayed on the electronic device DD has a desired gamma characteristic. The rendering circuit 112-4 may receive the image data from the controller 112-1, and render the image data in consideration of a pixel arrangement of the display panel 141 applied to the electronic device DD, or the like. At least one of the data conversion circuit 112-2, the gamma correction circuit 112-3, or the rendering circuit 112-4 may be integrated into other component (e.g., the main processor 111 or the controller 112-1). At least one of the data conversion circuit 112-2, the gamma correction circuit 112-3), or the rendering circuit 112-4 may be integrated into a data driver DDV to be described later.

The memory 120 may store various data used by at least one component (e.g., the processor 110 or the sensor module 161) of the electronic device DD, and input data or output data for relevant commands. The memory 120 may include at least one of the volatile memory 121 or the nonvolatile memory 122.

The input module 130 may receive a command or data to be used in a component (e.g., the processor 110, the sensor module 161, or the sound output module 163) of the electronic device DD from the outside of the electronic device DD (e.g., the user or the external electronic device 102).

The input module 130 may include a first input module 131 to which a command or data is input from the user, and a second input module 132 to which a command or data is input from the external electronic device 102. The first input module 131 may include a microphone, a mouse, a keyboard, a key (e.g., a button), or a pen (e.g., a passive pen or an active pen). The second input module 132 may support a designated protocol capable of being connected to the external electronic device 102 in a wired or wireless manner. According to an embodiment, the second input module 132 may include a high definition multimedia interface (HDMI), a universal serial bus (USB) interface, a secure digital (SD) card interface, or an audio interface. The second input module 132 may include a connector capable of being physically connected to the external electronic device 102, for example, an HDMI connector, a USB connector, an SD card connector, or an audio connector (e.g., a headphone connector).

The display module DM visually provides information for the user. The display module DM may include the display panel DP, a scan driver SDC and the data driver DDV. The display module DM may further include a window, a chassis, and a bracket for protecting the display panel DP.

The display panel DP may include a liquid crystal display panel, an organic light emitting display panel, or an inorganic light emitting display panel, and the type of the display panel DP is not particularly limited. The display panel DP may be a rigid type, or a flexible type capable of rolling or folding. The display module DM may further include a supporter which supports the display panel DP, a bracket, a heat dissipation member, or the like.

The scan driver SDC may be a driving chip and mounted on the display panel DP. Alternatively, the scan driver SDC may be integrated into the display panel DP. For example, the scan driver SDC may include an amorphous silicon TFT gate driver circuit (ASG), a low temperature polycrystalline silicon (LTPS) TFT gate driver circuit, or an oxide semiconductor TFT gate driver circuit (OSG), internalized into the display panel DP. The scan driver SDC receives a control signal from the controller 112-1, and outputs scan signals to the display panel DP in response to the control signal.

The display panel DP may further include a light emission driver. The light emission driver outputs an emission control signal to the display panel DP in response to the control signal received from the controller 112-1. The light emission driver may be separated from the scan driver SDC, or be integrated into the scan driver SDC.

The data driver DDV receives the control signal from the controller 112-1, and converts image data into analog voltages (e.g., data voltages) in response to the control signal and then outputs the data voltages to the display panel DP.

The data driver DDV may be incorporated into other component (e.g., the controller 112-1). The functions of the interface conversion circuit and timing control circuit of the controller 112-1 described herein may be incorporated into the data driver DDV.

The display module DM may further include the light emission driver, a voltage generation circuit, and the like. The voltage generating circuit may output various voltages supportive of driving the display panel DP.

The power module 150 supplies power to the components of the electronic device DD. The power module 150 may include a battery which charges a power voltage. The battery may include a non-rechargeable primary battery, a rechargeable secondary battery, or a fuel battery. The power module 150 may include a power management integrated circuit (PMIC). The PMIC supplies optimized power to each of the modules described herein and modules to be described later. The power module 150 may include a wireless power transmission/reception member electrically connected to the battery. The wireless power transmission/reception member may include a plurality of antenna radiators in the form of coils.

The electronic device DD may further include the built-in module 160 and the external module 170. The built-in module 160 may include the sensor module 161, the antenna module 162, and the sound output module 163. The external module 170 may include the camera module 171, a light module 172, and the communication module 173.

The sensor module 161 may detect an input by the user's body or an input by a pen of the first input module 131, and generate an electrical signal or data value corresponding to the input. The sensor module 161 may include at least one of the fingerprint sensor 161-1, the input sensor 161-2, or a digitizer 161-3.

The fingerprint sensor 161-1 may generate a data value corresponding to the user's fingerprint. The fingerprint sensor 161-1 may include one of an optical or capacitance fingerprint sensor.

The input sensor 161-2 may generate a data value corresponding to coordinate information of an input by the user's body or an input by a pen. The input sensor 161-2 generates a capacitance change due to the input as a data value. The input sensor 161-2 may detect an input by the passive pen or transmit/receive data to/from the active pen.

The input sensor 161-2 may measure a bio-signal such as, for example, blood pressure, moisture, or body fat. In an example in which the user touches part of the body to a sensor layer or a sensing panel and does not move for a certain period of time, the input sensor 161-2 may detect a bio-signal and output information desired by the user to the display module DM on the basis of a change in electric field caused by the part of the body.

The digitizer 161-3 may generate a data value corresponding to coordinate information of an input by the pen. The digitizer 161-3 generates an electromagnetic change by the input as a data value. The digitizer 161-3 may detect an input by the passive pen or transmit/receive data to/from the active pen.

At least one of the fingerprint sensor 161-1, the input sensor 161-2, or the digitizer 161-3 may be implemented as a sensor layer formed on the display panel DP through a continuous process. The fingerprint sensor 161-1, the input sensor 161-2, and the digitizer 161-3 may be disposed above the display panel DP, and any one of the fingerprint sensor 161-1, the input sensor 161-2, and the digitizer 161-3, for example, the digitizer 161-3, may be disposed below the display panel DP.

At least two of the fingerprint sensor 161-1, the input sensor 161-2, and the digitizer 161-3 may be integrated into one sensing panel through the same process. In an example in which the at least two are integrated into the one sensing panel, the sensing panel may be disposed between the display panel DP and a window disposed above the display panel DP. According to an embodiment, the sensing panel may be disposed on the window, and the position of the sensing panel is not particularly limited.

At least one of the fingerprint sensor 161-1, the input sensor 161-2, or the digitizer 161-3 may be built in the display panel DP. That is, at least one of the fingerprint sensor 161-1, the input sensor 161-2, or the digitizer 161-3 may be simultaneously formed through a process of forming elements (e.g., light emitting elements, transistors, or the like) included in the display panel DP.

In some aspects, the sensor module 161 may generate an electrical signal or data value corresponding to an internal state or external state of the electronic device DD. The sensor module 161 may further include, for example, a gesture sensor, a gyro sensor, a barometric pressure sensor, a magnetic sensor, an acceleration sensor, a grip sensor, a proximity sensor, a color sensor, an IR (infrared) sensor, a biosensor, a temperature sensor, a humidity sensor, or an illuminance sensor.

The antenna module 162 may include one or more antennas for transmitting a signal or power to the outside or receiving a signal or power from the outside. According to an embodiment, the communication module 173 may transmit a signal to an external electronic device or receive a signal from the external electronic device through an antenna suitable for a communication method. An antenna pattern of the antenna module 162 may be integrated into one component (e.g., the display panel DP) of the display module DM, the input sensor 161-2, or the like.

The sound output module 163 may be a device for outputting a sound signal to the outside of the electronic device DD, and include, for example, a speaker used for general purposes such as, for example, multimedia playback or recording playback and a receiver used exclusively for receiving calls. According to an embodiment, the receiver may be provided integrally with or separately from the speaker. A sound output pattern of the sound output module 163 may be integrated into the display module DM.

The camera module 171 may photograph still images and moving images. According to an embodiment, the camera module 171 may include one or more lenses, image sensors, or image signal processors. The camera module 171 may further include an infrared camera capable of measuring the presence/absence of a user, the user's position, the user's gaze, or the like.

The light module 172 may provide light. The light module 172 may include a light emitting diode or a xenon lamp. The light module 172 may operate in conjunction with the camera module 171 or operate independently.

The communication module 173 may establish a wired or wireless communication channel between the electronic device DD and the external electronic device 102, and support communication through the established communication channel. The communication module 173 may include one or all of a wireless communication module such as, for example, a cellular communication module, a short-range wireless communication module, or a global navigation satellite system (GNSS) communication module, and a wired communication module such as, for example, a local area network (LAN) communication module or a power line communication module. The communication module 173 may communicate with the external electronic device 102 through a short-range communication network such as, for example, Bluetooth, WiFi direct, or infrared data association (IrDA), or a long-range communication network such as, for example, cellular network, Internet, or computer network (e.g., LAN or WAN). The foregoing various types of communication modules 173 may be implemented as a single chip, or implemented as separate chips, respectively.

The input module 130, the sensor module 161, the camera module 171, and the like may be utilized to control the operation of the display module DM in conjunction with the processor 110.

The processor 1110 outputs a command or data to the display module DM, the sound output module 163, the camera module 171, or the light module 172, based on input data received from the input module 130. For example, the processor 110 may generate image data in response to the input data input through a mouse, an active pen, or the like, and output the image data to the display module DM, or may generate command data in response to the input data and output the command data to the camera module 171 or the light module 172. In an example in which the input data is not received from the input module 130 for a certain period of time, the processor 110 may convert an operation mode of the electronic device DD into a low power mode or a sleep mode, thereby reducing power consumed by the electronic device DD.

The processor 110 outputs a command or data to the display module DM, the sound output module 163, the camera module 171, or the light module 172, based on sensing data received from the sensor module 161. For example, the processor 110 may compare authentication data input by the fingerprint sensor 161-1 with authentication data stored in the memory 120 and then execute an application according to a result of the comparison. The processor 110 may execute a command, based on sensing data detected by the input sensor 161-2 or the digitizer 161-3, or output corresponding image data to the display module DM. In an example in which the sensor module 161 includes a temperature sensor, the processor 110 may receive temperature data for temperatures measured from the sensor module 161 and further perform a luminance correction, or the like on the image data, based on the temperature data.

When processor 110 may receive measurement data about the presence/absence of a user, the position of the user, the user's gaze, or the like from the camera module 171. The processor 110 may further perform the luminance correction or the like on the image data, based on the measurement data. For example, the processor 110 having determined the presence/absence of a user through an input from the camera module 171 may output, to the display module DM, image data in which the luminance is corrected through the data conversion circuit 112-2 or the gamma correction circuit 112-3.

Some of the foregoing components may be connected to each other through a communication method between peripheral devices, for example, a bus, a general purpose input/output (GPIO), a serial peripheral interface (SPI), a mobile industry processor interface (MIPI), or a ultra path interconnect (UPI) link, and exchange signals (e.g., commands or data) with each other. The processor 110 may communicate with the display module DM through an appointed interface. For example, any one of the foregoing communication methods may be used, and the communication method is not limited to the foregoing communication methods.

The electronic devices DD according to various embodiments set forth herein may be various types of devices. The electronic device DD may include, for example, at least one of a portable communication device (e.g., a smartphone), a computer device, a portable multimedia device, a portable medical device, a camera, a wearable device, or a home appliance. The electronic device DD according to an embodiment herein is not limited to the foregoing devices.

FIG. 2 is a view illustrating an example of a cross-section of the electronic device illustrated in FIG. 1A. As an example, FIG. 2 illustrates a cross-section of the electronic device DD when viewed in the second direction DR2. Some of the components of the electronic device DD described with reference to FIG. 1B are omitted in FIG. 2.

Referring to FIG. 2, the electronic device DD may include a display panel DP, an input sensor ISP, an anti-reflective layer RPL, a window WIN, a panel protective film PPF, and first and second adhesive layers AL1 and AL2. The input sensor ISP illustrated in FIG. 2 may be the same component as the input sensor 161-2 described with reference to FIG. 1B.

The display panel DP according to an embodiment of the inventive concept may be an emissive display panel. For example, the display panel DP may be an organic light emitting display panel or an inorganic light emitting display panel. An emission of the organic light emitting display panel may include an organic light emitting material. An emission layer of the inorganic light emitting display panel may include a quantum dot, a quantum rod, and the like. Hereinafter, the display panel DP is described as the organic light emitting display panel.

The input sensor ISP may be disposed on the display panel DP. The input sensor ISP may include a plurality of sensing parts (not illustrated) for sensing an external input by using a capacitance method. The input sensor ISP may be directly manufactured on the display panel DP during manufacture of the electronic device DD. Thus, the input sensor ISP according to an embodiment may be directly disposed on the display panel DP. However, the input sensor ISP is not limited thereto, and may be manufactured as a separate panel from the display panel DP to be attached to the display panel DP through an adhesive layer.

The anti-reflective layer RPL may be disposed on the input sensor ISP. The anti-reflective layer RPL may be directly manufactured on the input sensor ISP during the manufacture of the electronic device DD. However, the anti-reflective layer RPL is not limited thereto, and may be manufactured as a separate panel to be attached to the input sensor ISP through an adhesive layer.

The anti-reflective layer RPL may be defined as a film that prevents the reflection of external light. The anti-reflective layer RPL may reduce the reflectance of external light incident from above the electronic device DD toward the display panel DP. The external light may not be visible to a user due to the anti-reflective layer RPL.

When external light traveling toward the display panel DP is reflected by the display panel DP and provided for an external user again, the external light may be visible to the user like a mirror. To prevent such a phenomenon, the anti-reflective layer RPL may include, for example, a plurality of color filters that emit the same colors as pixels of the display panel DP, respectively.

The color filters may filter the external light and have the same colors as the pixels. In this case, the external light may be invisible to the user. However, embodiments of the present disclosure are not limited thereto, and the anti-reflective layer RPL may include a retarder and/or a polarizer in order to reduce the reflectance of the external light.

The window WIN may be disposed on the anti-reflective layer RPL. The window WIN may protect the display panel DP, the input sensor ISP, and the anti-reflective layer RPL from external scratches and impact.

The panel protective film PPF may be disposed below the display panel DP. The panel protective film PPF may protect a lower portion of the display panel DP. The panel protective film PPF may include a flexible plastic material such as, for example, polyethylene terephthalate (PET).

The first adhesive layer AL1 may be disposed between the display panel DP and the panel protective film PPF, and the display panel DP and the panel protective film PPF may be bonded to each other through the first adhesive layer AL1. The second adhesive layer AL2 may be disposed between the window WIN and the anti-reflective layer RPL, and the window WIN and the anti-reflective layer RPL may be bonded to each other through the second adhesive layer AL2.

FIG. 3 is a view illustrating an example of a cross-section of the display panel illustrated in FIG. 2. As an example, FIG. 3 illustrates a cross-section of a display panel DP when viewed in the second direction DR2.

Referring to FIG. 3, the display panel DP may include a substrate SUB, a circuit layer DP-CL disposed on the substrate SUB, a light emitting element layer DP-OLED disposed on the circuit layer DP-CL, and an encapsulation layer TFE disposed on the light emitting element layer DP-OLED.

The substrate SUB may include a display area DA and a non-display area NDA around the display area DA. The substrate SUB may include glass, or a flexible plastic material such as, for example, polyimide. The light emitting element layer DP-OLED may be disposed on the display area DA.

A plurality of pixels may be disposed in the circuit layer DP-CL and the light emitting element layer DP-OLED. Each of the pixels may include a transistor disposed in the circuit layer DP-CL, and a light emitting element disposed in the light emitting element layer DP-OLED and connected to the transistor.

The encapsulation layer TFE may be disposed on the circuit layer DP-CL and cover the light emitting element layer DP-OLED. The encapsulation layer ECL may protect the pixels from moisture, oxygen, and external foreign substances. The encapsulation layer TFE may include inorganic layers and an organic layer. The organic layer may be disposed between the inorganic layers and sealed from the inorganic layers to provide a flat surface. According to an embodiment, the organic layer may be disposed on the inorganic layers or omitted, and is not limited to any one embodiment.

FIG. 4A is a block diagram of the electronic device illustrated in FIG. 1A.

Referring to FIG. 4A, an electronic device DD may include a display panel DP, a timing controller T-C, a scan driver SDC, a data driver DDV, a light emission driver EDV, and a voltage generator VG.

The display panel DP may include a plurality of scan lines GIL1 to GILm, GCL1 to GCLm, GWL1 to GWLm and GBL1 to GBLm, a plurality of emission lines EML1 to EMLm, a plurality of data lines DL1 to DLn, and a plurality of pixels PX. Here, m and n are each a natural number.

The pixels PX may be electrically connected to the scan lines GIL1 to GILm, GCL1 to GCLm, GWL1 to GWLm and GBL1 to GBLm, the emission lines EML1 to EMLm, and the data lines DL1 to DLn, respectively. Each of the pixels PX may be electrically connected to four corresponding scan lines, one corresponding data line, and one corresponding emission line.

The scan lines GIL1 to GILm, GCL1 to GCLm, GWL1 to GWLm and GBL1 to GBLm may include a plurality of initialization scan lines GIL1 to GILm, a plurality of compensation scan lines GCL1 to GCLm, a plurality of write scan lines GWL1 to GWLm, and a plurality of bias scan lines GBL1 to GBLm.

Each of the pixels PX may be connected to a corresponding one of the initialization scan lines GIL1 to GILm, a corresponding one of the compensation scan lines GCL1 to GCLm, a corresponding one of the write scan lines GWL1 to GWLm, and a corresponding one of the bias scan lines GBL1 to GBLm.

The scan lines GIL1 to GILm, GCL1 to GCLm, GWL1 to GWLm and GBL1 to GBLm may be connected to the scan driver SDC, and extend in the first direction DR1 to be arranged in the second direction DR2. The emission lines EML1 to EMLm may be connected to the light emission driver EDV, and extend in the first direction DR1 to be arranged in the second direction DR2. The data lines DL1 to DLn may be connected to the data driver DDV, and extend in the second direction DR2 to be arranged in the first direction DR1.

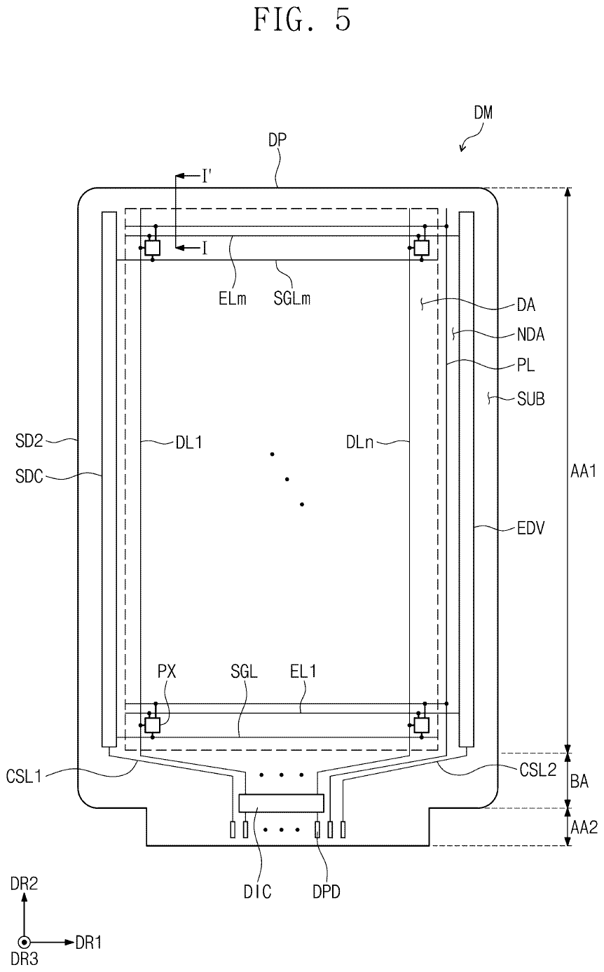

The scan driver SDC, the light emission driver EDV, and the data driver DDV may be substantially disposed on the display panel DP, and this configuration will be illustrated in FIG. 5 later.

The timing controller T-C may receive an image signal RGB and a control signal CTRL. The timing controller T-C may generate an image data signal DAS obtained by converting a data format of the image signal RGB to match an interface specification of the data driver DDV. The timing controller T-C may output a scan control signal SCS, a data control signal DCS, and an emission control signal ECS in response to the control signal CTRL.

The voltage generator VG may generate voltages for an operation of the display panel DP. The voltage generator VG may generate a first driving voltage ELVDD, a second driving voltage ELVSS, a first initialization voltage VINT, and a second initialization voltage VAINT. The first driving voltage ELVDD, the second driving voltage ELVSS, the first initialization voltage VINT, and the second initialization voltage VAINT may be applied to the pixels PX.

The scan driver SDC may receive the scan control signal SCS from the timing controller T-C. The scan driver SDC may output scan signals to the scan lines GIL1 to GILm, GCL1 to GCLm, GWL1 to GWLm, and GBL1 to GBLm in response to the scan control signal SCS. The scan signals may be applied to the pixels PX through the scan lines GIL1 to GILm, GCL1 to GCLm, GWL1 to GWLm, and GBL1 to GBLm.

The data driver DDV may receive the data control signal DCS and the image data signal DAS from the timing controller T-C. The data driver DDV may convert the image data signal DAS into data signals and output the data signals. The data signals may be defined as analog voltages corresponding to gray levels of the image data signal DAS. The data signals may be applied to the pixels PX through the data lines DL1 to DLn.

The light emission driver EDV may receive the emission control signal ECS from the timing controller T-C. The light emission driver EDV may output emission signals to the emission lines EML1 to EMLm in response to the emission control signal ECS. The emission signals may be applied to the pixels PX through the emission lines EML1 to EMLm.

The pixels PX may receive the data voltages in response to the scan signals. The pixels PX may display an image by emitting light with luminance corresponding to the data voltages in response to the emission signals.

FIG. 4B is a view illustrating an equivalent circuit of one of the pixels illustrated in FIG. 4A.

As an example, FIG. 4B illustrates a PXij connected to a j-th data line DLj, i-th scan lines GWLi, GCLi, GILi and GBLi, and an i-th emission line EMLi. Here, i and j are each a natural number.

Referring to FIG. 4B, the pixel PXij may include a pixel circuit PC and a light emitting element OLED connected to the pixel circuit PC. The pixel circuit PC may drive the light emitting element OLED.

The pixel circuit PC may include a plurality of transistors T1 to T8 and a capacitor CST. The transistors T1 to T8 and the capacitor CST may control an amount of current flowing through the light emitting element OLED. The light emitting element OLED may generate light having a certain luminance according to an amount of received current.

An i-th write scan line GWLi may receive an i-th write scan signal GWi, and an i-th compensation scan line GCLi may receive an i-th compensation scan signal GCi. An i-th initialization scan line GILi may receive an i-th initialization scan signal GIi, and an i-th bias scan line GBLi may receive an i-th bias scan signal GBi. The i-th emission line EMLi may receive an i-th emission signal EMi.

The pixel PXij may be connected to the j-th data line DLj, the i-th write scan line GWLi, the i-th compensation scan line GCLi, the i-th initialization scan line GILi, the i-th bias scan line GBLi, the i-th emission line EMLi, a first initialization line VIL1, a second initialization line VIL2, a bias line VBL, and first and second power lines PL1 and PL2.

The first initialization line VIL1 may receive a first initialization voltage VINT, and the second initialization line VIL2 may receive a second initialization voltage VAINT. The bias line VBL may receive a bias voltage VBIAS. The first power line PL1 may receive a first driving voltage ELVDD, and the second power line PL2 may receive a second driving voltage ELVSS.

Each of the transistors T1 to T8 may include a source electrode, a drain electrode, and a gate electrode. Hereinafter, for the sake of convenience, in FIG. 4B, one of the source electrode and the drain electrode is defined as a first electrode, and the other is defined as a second electrode. In some aspects, the gate electrode is defined as a control electrode.

The transistors T1 to T8 may include first to eighth transistors T1 to T8. The first, second, and fifth to eighth transistors T1, T2 and T5 to T8 may be PMOS transistors. The third and fourth transistors T3 and T4 may be NMOS transistors.

The first transistor T1 may be defined as a driving transistor, and the second transistor T2 may be defined as a switching transistor. The third transistor T3 may be defined as a compensation transistor. The fourth transistor T4 and the seventh transistor T7 may each be defined as an initialization transistor. The fifth transistor T5 and the sixth transistor T6 may each be defined as an emission control transistor. The eighth transistor T8 may be defined as a bias transistor.

The light emitting element OLED may be defined as an organic light emitting element. The light emitting element OLED may include a first electrode AE and a second electrode CE. The first electrode AE may receive the first driving voltage ELVDD through the sixth, first, and fifth transistors T6, T1 and T5. The first driving voltage ELVDD may be applied to the pixel circuit PC through the first power line PL1.

The second electrode CE may receive the second driving voltage ELVSS having a lower level than the first driving voltage ELVDD. The second driving voltage ELVSS may be applied to the pixel circuit PC through the second power line PL2.

The first transistor T1 may be disposed between the fifth transistor T5 and the sixth transistor T6 and be connected to the fifth transistor T5 and the sixth transistor T6. The first transistor T1 may be connected to the first power line PL1 through the fifth transistor T5 and be connected to the first electrode AE through the sixth transistor T6.

The first transistor T1 may include a first electrode connected to the first power line PL1 through the fifth transistor T5, a second electrode connected to the first electrode AE through the sixth transistor T6, and a control electrode connected to a first node N1.

The first electrode of the first transistor T1 may be connected to the fifth transistor T5, and the second electrode of the first transistor T1 may be connected to the sixth transistor T6. The first transistor T1 may control an amount of current flowing through the light emitting element OLED according to a voltage of the first node N1, which is applied to the control electrode of the first transistor T1.

The second transistor T2 may be disposed between the first transistor T1 and the j-th data line DLj, and be connected to the first transistor T1 and the j-th data line DLj. The second transistor T2 may include a first electrode connected to the j-th data line DLj, a second electrode connected to the first electrode of the first transistor T1, and a control electrode connected to the i-th write scan line GWLi.

The second transistor T2 may be turned on in response to the i-th write scan signal GWi received through the i-th write scan line GWLi, and electrically connect the j-th data line DLj to the first electrode of the first transistor T1. The second transistor T2 may perform a switching operation of providing a data voltage VD (corresponding to the data signal described herein), received through the j-th data line DLj, to the first electrode of the first transistor T1.

The third transistor T3 may be connected to the first node N1 and the second electrode of the first transistor T1. The third transistor T3 may include a first electrode connected to the second electrode of the first transistor T1, a second electrode connected to the first node N1, and a control electrode connected to the i-th compensation scan line GCLi.

The third transistor T3 may be turned on in response to the i-th compensation scan signal GCi received through the i-th compensation scan line GCLi, and electrically connect the second electrode of the first transistor T1 to the control electrode of the first transistor T1. In an example in which the third transistor T3 is turned on, the first transistor T1 and the third transistor T3 may be diode-connected.

The fourth transistor T4 may be connected to the first node N1. The fourth transistor T4 may include a first electrode connected to the first node N1, a second electrode connected to the first initialization line VIL1, and a control electrode connected to the i-th initialization scan line GILi. The fourth transistor T4 may be turned on in response to the i-th initialization scan signal GIi received through the i-th initialization scan line GILi, and provide the first initialization voltage VINT, received through the first initialization line VIL1, to the first node N1.

The fifth transistor T5 may include a first electrode connected to the first power line PL1, a second electrode connected to the first electrode of the first transistor T1, and a control electrode connected to the i-th emission line EMLi.

The sixth transistor T6 may include a first electrode connected to the second electrode of the first transistor T1, a second electrode connected to the first electrode AE, and a control electrode connected to the i-th emission line EMLi.

The fifth transistor T5 and the sixth transistor T6 may be turned on in response to the i-th emission signal EMi received through the i-th emission line EMLi. The first driving voltage ELVDD may be provided to the light emitting element OLED by the turned-on fifth transistor T5 and sixth transistor T6 such that driving current flows through the light emitting element OLED. Accordingly, the light emitting element OLED may emit light.

The seventh transistor T7 may include a first electrode connected to the first electrode AE, a second electrode connected to the second initialization line VIL2, and a control electrode connected to the i-th bias scan line GBLi. The seventh transistor T7 may be turned on in response to the i-th bias scan signal GBi received through the i-th bias scan line GBLi, and provide the second initialization voltage VAINT, received through the second initialization line VIL2, to the first electrode AE of the light emitting element OLED.

In an embodiment of the inventive concept, the second initialization voltage VAINT may have a different level from the first initialization voltage VINT. However, the second initialization voltage VAINT is not limited thereto, and may have the same level as the first initialization voltage VINT.

The seventh transistor T7 may improve black display performance of the pixel PXij. In an example in which the seventh transistor T7 is turned on, a parasitic capacitor (not illustrated) of the light emitting element OLED may be discharged. Thus, when a black luminance is implemented, the light emitting element OLED may not emit light due to leakage current from the first transistor T1, and accordingly, the black display performance may be improved.

The capacitor CST may include a first electrode connected to the first power line PL1, and a second electrode connected to the first node N1. In an example in which the fifth transistor T5 and the sixth transistor T6 are turned on, an amount of current flowing through the first transistor T1 may be determined according to a voltage stored in the capacitor CST.

The eighth transistor T8 may include a first electrode connected to the bias line VBL, a second electrode connected to the first electrode of the first transistor T1, and a control electrode connected to the i-th bias scan line GBLi.

The eighth transistor T8 may be turned on in response to the i-th bias scan signal GBi and provide the bias voltage VBIAS, received through the bias line VBL, to the first electrode of the first transistor T1. However, the transistors included in the pixel PXij are not limited thereto.

FIG. 5 is a plan view of a display module according to an embodiment of the inventive concept.

Referring to FIG. 5, a display module DM may include a display panel DP, a scan driver SDC and a data driver DDV. The display panel DP generates an image IM. FIG. 5 illustrates some of components of the display panel DP on a plane.

For ease of explanation, FIG. 5 illustrates some components of the display module DM in block form. Referring to FIG. 5, the display module DM may include a base substrate SUB, the scan driver SDC, a light emission driver EDV, a driving chip DIC, a plurality of panel signal lines SGL1 to SGLm, DL1 to DLn, EL1 to ELm, CSL1, CSL2 and PL, a plurality of pixels PX, and a plurality of display pads DPD.

The base substrate SUB includes a first base area AA1, a second base area AA2, and a bending area BA which are divided in the second direction DR2. The second base area AA2 and the bending area BA may each be a partial area of a non-display area NDA. The bending area BA is disposed between the first base area AA1 and the second base area AA2.

The first base area AA1 is an area including the display surface DS in FIG. 1A. The second base area AA2 is spaced apart from the first base area AA1 with the bending area BA disposed between the first and second base areas AA1 and AA2. Each of the second base area AA2 and the bending area BA may have a smaller width than the first base area AA1 in the first direction DR1. That is, in the first direction DR1, a length of each of the bending area BA and the second base area AA2 may be smaller than a length of the first base area AA1.

An area having a small length in a bending-axis direction may be more easily bent. However, this is illustrated as an example, and each of the second base area AA2 and the bending area BA may have the same width as the first base area AA1, and is not limited to any one embodiment.

The bending area BA is bent around a bending axis extending in the first direction DR1. In an example in which the bending area BA is not bent, the second base area AA2 may faces the same direction as the first base area AA1, and when the bending area BA is bent, the second base area AA2 may face an opposite direction to the first base area AA1.

Although not illustrated, the display module DM may further include a circuit board physically connected to the second base area AA2. As the bending area BA is bent, the circuit board is disposed on a rear surface of an electronic panel. Accordingly, an area which defines the display surface DS may be the first base area AA1, and the second base area AA2 and the bending area BA are not visible through the display surface DS. Thus, a bezel area of the electronic device DD may be reduced.

Each of the pixels PX includes a light emitting element and a thin film transistor connected to the light emitting element. A shape of the display panel DP illustrated in FIG. 5 is substantially the same as a planar shape of the base layer described herein. In this embodiment, a display area DA and a non-display area NDA may be divided based on whether or not the light emitting element is disposed.

FIG. 5 illustrates the pixels PX which are disposed in the display area DA. The display area DA may be an area on which the image IM is displayed. However, this is illustrated as an example. A portion of components of each of the pixels PX may include the thin film transistor disposed in the non-display area NDA, and the pixels PX are not limited to any one embodiment.

The scan driver SDC, the driving chip DIC, and the light emission driver EDV may be disposed in the non-display area NDA. The driving chip DIC may include the data driver described herein.

The panel signal lines SGL to SGLm, DL1 to DLn, EL1 to ELm, CSL1, CSL2 and PL may include a plurality of scan lines SGL to SGLm, a plurality of data lines DL1 to DLn, a plurality of emission lines EL1 to ELm, first and second control lines CSL1 and CSL2, and a power line PL. Among the panel signal lines SGL to SGLm, DL1 to DLn, EL1 to ELm, CSL1, CSL2 and PL, the data lines DL1 to DLn, the first and second control lines CSL1 and CSL2, and the power line PL may be connected a plurality of display pads DPD, respectively. Here, m and n are each a natural number. The pixels PX may be connected to the scan lines SGL to SGLm, the data lines DL1 to DLn, and the emission lines EL1 to ELm.

The scan lines SGL to SGLm may correspond to at least one of the scan lines GIL1 to GILm, GCL1 to GCLm, GWL1 to GWLm and GBL1 to GBLm described with reference to FIG. 4A. The scan lines SGL to SGLm may extend in the second direction DR2 to be connected to the scan driver SDC. The data lines DL1 to DLn may extend in the second direction DR2 to be connected to the driving chip DIC via the bending area BA. The emission lines EL1 to ELm may extend in the first direction DR1 to be connected to the light emission driver EDV.

The power line PL may include a portion extending in the second direction DR2 and a portion extending in the first direction DR1. The portion extending in the first direction DR1 and the portion extending in the second direction DR2 may be disposed at different layers. The portion, which extends in the second direction DR2, of the power line PL may extend to the second base area AA2 via the bending area BA. The power line PL may provide a first voltage to the pixels PX.

The first control line CSL1 may be connected to the scan driver SDC and extend toward a lower end of the second base area AA2 via the bending area BA. The second control line CSL2 may be connected to the light emission driver EDV and extend toward the lower end of the second base area AA2 via the bending area BA.

The display pads DPD may be disposed adjacent to the lower end of the second base area AA2 when viewed on a plane. The driving chip DIC, the power line PL, the first control line CSL1, and the second control line CSL2 may be connected to the display pads DPD. A circuit board MB may be electrically connected to the display pads DPD through an anisotropic conductive adhesive layer. A circuit board MB may be electrically connected to the display pads DPD through an anisotropic conductive adhesive layer.

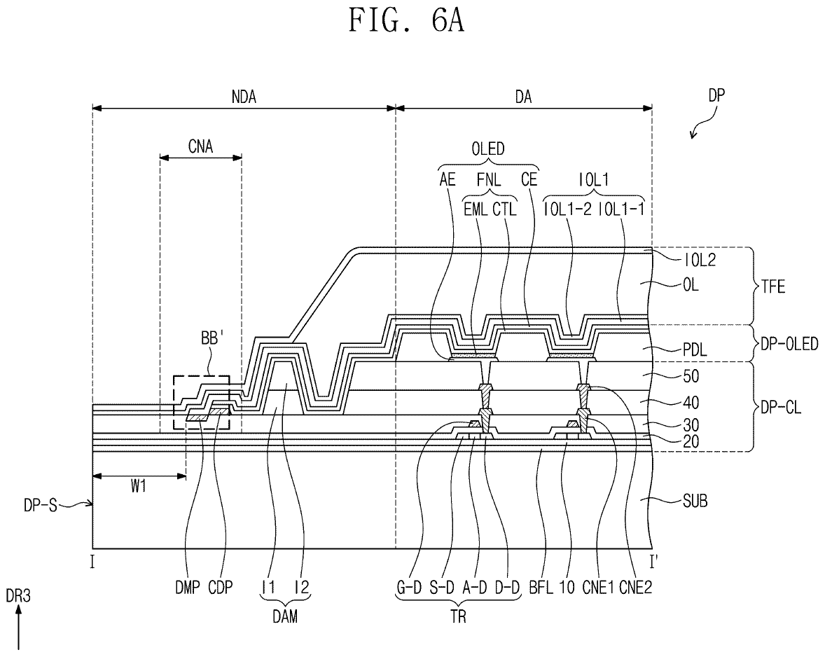

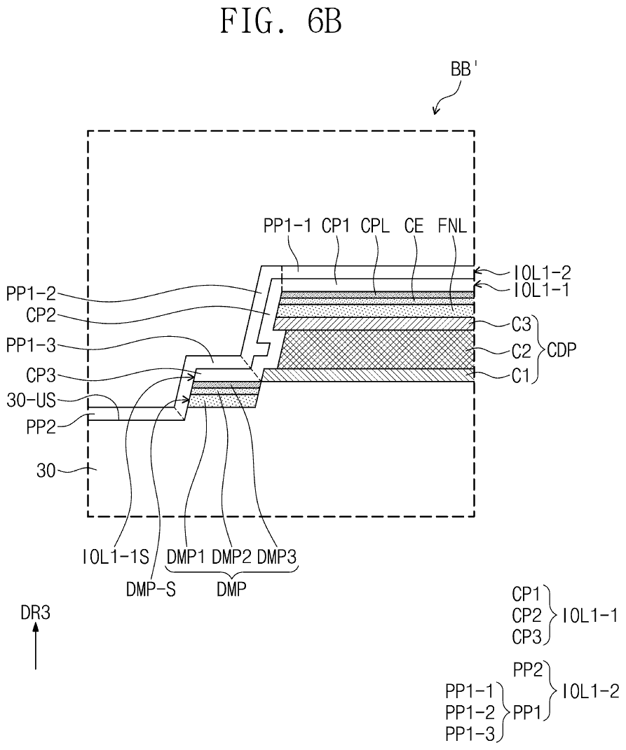

FIG. 6A is a cross-sectional view of a portion of a display panel according to an embodiment of the inventive concept. FIG. 6B is an enlarged cross-sectional view of a portion of a display panel according to an embodiment of the inventive concept. FIG. 6A illustrates a cross-section taken along line I-I′ illustrated in FIG. 5. FIG. 6B is an enlarged cross-sectional view of area BB′ illustrated in FIG. 6A.

Referring to FIG. 6A, a display panel DP may include a base substrate SUB and a plurality of insulating layers 10, 20, 30, 40 and 50 disposed on the base substrate SUB. Components constituting the signal lines SGL to SGLm, DL1 to DLn, EL1 to ELm, CSL1, CSL2 and PL described herein and components constituting the scan driver SDC described herein may be disposed between the base substrate SUB and the insulating layers 10, 20, 30, 40 and 50. The components constituting the plurality of insulating layers 10, 20, 30, 40 and 50, the signal lines SGL to SGLm, DL1 to DLn, EL1 to ELm, CSL1, CSL2 and PL, and the scan driver SDC may be included in a circuit layer DP-CL.

The base substrate SUB has an insulating property. The base substrate SUB may have flexibility such that the base substrate SUB is bendable. For example, the base substrate SUB may be an insulating polymer film.

A buffer layer BFL may be disposed on the base substrate SUB. The buffer layer BFL may improve a bonding force between the base substrate SUB and a semiconductor pattern and/or a conductive pattern and prevent foreign matter from being introduced from the outside. The buffer layer BFL may include at least one of a silicon oxide layer or a silicon nitride layer. The silicon oxide layer and the silicon nitride layer may be alternately stacked.

The first insulating layer 10 may be disposed on the buffer layer BFL. The pixels PX (see FIG. 5) may be disposed on the first insulating layer 10. As an example, FIG. 6A illustrates some components of one pixel PX. The pixel PX may include a transistor TR and a light emitting element OLED.

The transistor TR may be electrically connected to the light emitting element OLED. A source S-D, an active A-D, and a drain D-D of the transistor TR may be provided from the semiconductor pattern. The semiconductor pattern may include a silicon semiconductor, and may include a monocrystalline silicon semiconductor, a polycrystalline silicon semiconductor, or an amorphous silicon semiconductor. Alternatively, the semiconductor pattern may include an oxide semiconductor. The semiconductor pattern according to an embodiment of the inventive concept may have various materials having semiconductor properties, and is not limited to any one embodiment.

The semiconductor pattern has different electrical properties according to whether or not the semiconductor pattern is doped. The semiconductor pattern may include a doped region and a non-doped region. The doped region may be doped with an n-type dopant or a p-type dopant. A p-type transistor includes a doped region doped with the p-type dopant. The doped region has higher conductivity than the non-doped region, and substantially serves as an electrode or a signal line. The non-doped region substantially corresponds to an active region of a transistor. In other words, one portion of the semiconductor pattern may be the active A-D of the transistor TR, and another portion of the semiconductor pattern may be the source S-D or the drain D-D of the transistor TR.

A second insulating layer 20 may cover the source S-D, the active A-D, and the drain D-D of the transistor TR disposed on the first insulating layer 10. A gate G-D of the transistor TR may be disposed on the second insulating layer 20. A third insulating layer 30 may be disposed on the second insulating layer 20 and cover the gate G-D. The gate G-D may overlap the active A-D on a plane. The gate G-D may function as a mask in a process of doping the semiconductor pattern.

A fourth insulating layer 40 may be disposed on the third insulating layer 30. The fourth insulating layer 40 may be an organic layer, and may have a single-layer or multilayer structure. For example, the fourth insulating layer 40 may be a polyimide-based resin layer having a single-layer structure. However, embodiments of the present disclosure are not limited thereto, and the fourth insulating layer 40 may include at least one of acrylic resin, methacrylic resin, polyisoprene-based resin, vinyl-based resin, epoxy-based resin, urethane-based resin, cellulose-based resin, siloxane-based resin, polyamide-based resin, or perylene-based resin.

A first connection electrode CNE1 may be disposed on the third insulating layer 30, and a second connection electrode CNE2 may be disposed on the fourth insulating layer 40. The first connection electrode CNE1 may pass through the second insulating layer 20 and the third insulating layer 30 and be electrically connected to a portion of the semiconductor pattern, for example, the drain D-D. The second connection electrode CNE2 may pass through the fourth insulating layer 40 and be electrically connected to the first connection electrode CNE1.

One of the first connection electrode CNE1 and the second connection electrode CNE2 may be omitted. Alternatively, an additional connection electrode which connects the light emitting element OLED and the transistor TR may be further disposed. A method for an electrical connection between the light emitting element OLED and transistor TR may be variously changed according to the number of the insulating layers disposed between the light emitting element OLED and transistor TR, and is not limited to any one embodiment.

A fifth insulating layer 50 may be disposed on the fourth insulating layer 40 and cover the second connection electrode CNE2. The fifth insulating layer 50 may be an organic layer or an inorganic layer, and may have a single-layer or multilayer structure. The plurality of insulating layers 10, 20, 30, 40 and 50 and the transistor TR correspond to the circuit layer DP-CL described with reference to FIG. 2. At least a portion of a top surface of each of the plurality of insulating layers 10, 20, 30, 40 and 50 may have a flat surface parallel to a top surface of the base substrate SUB.

The light emitting element OLED may be disposed on the fifth insulating layer 50. The light emitting element OLED may include a first electrode AE, a functional layer FNL, and a second electrode CE. The first electrode AE may be electrically connected to the transistor TR through the first connection electrode CNE1 and the second connection electrode CNE2. The first electrode AE may be, for example, an anode.

A pixel definition layer PDL is disposed on the fifth insulating layer 50 and exposes at least a portion of the first electrode AE. The pixel definition layer PDL may be an inorganic layer, an organic layer, or a combination thereof, and may have a single-layer or multilayer structure. As used herein, the pixel definition layer PDL and the light emitting element OLED correspond to the light emitting element layer DP-OLED described herein.

The functional layer FNL may be disposed on the first electrode AE. The functional layer FNL may include at least an emission layer EML. The emission layer EML may provide light of a certain color. In this embodiment, the emission layer EML patterned and having a single-layer structure is illustrated as an example, but embodiments of the present disclosure are not limited thereto. For example, the emission layer EML may have a multilayer structure. In some aspects, the emission layer EML may extend toward a top surface of the pixel definition layer PDL and be provided, in common, to a plurality of pixels. The second electrode CE may be disposed on the emission layer EML. The second electrode CE may be, for example, a cathode.

The functional layer FNL may further include a charge control layer CTL. The charge control layer CTL may be disposed between the first electrode AE and the second electrode CE. As an example, FIG. 6A illustrates the charge control layer CTL which is disposed between the second electrode CE and the emission layer EML, but the charge control layer CTL is not limited thereto and may be provided between the first electrode AE and the emission layer EML. The charge control layer CTL may include an electron control layer (or an electron control region) disposed between the second electrode CE and the emission layer EML, and a hole control layer (or a hole control region) disposed between the first electrode AE and the emission layer EML. The charge control layer CTL may be provided, in common, to the plurality of pixels.

The light emitting element OLED may further include a capping layer CPL (see FIG. 6B) disposed on the second electrode CE. The capping layer CPL may be provided to protect a component disposed below the capping layer CPL and improve optical properties of the light emitting element OLED. The capping layer CPL may have a refractive index of about 1.6 or less in a visible wavelength range.

An encapsulation layer TFE is disposed on the pixel definition layer PDL and covers the light emitting element OLED. The encapsulation layer TFE includes at least an inorganic layer. The encapsulation layer TFE may include a plurality of inorganic encapsulation layers, and at least one organic encapsulation layer disposed between the plurality of inorganic encapsulation layers. In an embodiment, the encapsulation layer TFE may include a lower inorganic encapsulation layer IOL1, an organic encapsulation layer OL, and an upper inorganic encapsulation layer IOL2.

The lower inorganic encapsulation layer IOL1 may be disposed on the second electrode CE. The organic encapsulation layer OL may be disposed on the lower inorganic encapsulation layer IOL1. The upper inorganic encapsulation layer IOL2 may be disposed on the organic encapsulation layer OL and cover the organic encapsulation layer OL. The lower inorganic encapsulation layer IOL1 and the upper inorganic encapsulation layer IOL2 may each include a silicon nitride layer, a silicon oxynitride layer, a silicon oxide layer, a titanium oxide layer, an aluminum oxide layer, or the like, but are not particularly limited thereto. The organic encapsulation layer OL may include an acrylic organic layer or a silicon-based layer, and is not particularly limited. The lower inorganic encapsulation layer IOL1 and the upper inorganic encapsulation layer IOL2 may protect the light emitting element OLED from moisture/oxygen or foreign matter.

The lower inorganic encapsulation layer IOL1 includes a plurality of inorganic layers. The lower inorganic encapsulation layer IOL1 includes a first inorganic layer IOL1-1 which is disposed on the second electrode CE and covers the light emitting element OLED, and a second inorganic layer IOL1-2 which is disposed on the first inorganic layer IOL1-1. The second inorganic layer IOL1-2 may be directly disposed on the first inorganic layer IOL1-1, and the organic encapsulation layer OL may be directly disposed on the second inorganic layer IOL1-2.

The display panel DP may further include a dam structure DAM disposed in a non-display area NDA. The dam structure DAM may be disposed at an edge of the display module DM and prevent overflow of the organic encapsulation layer OL.

The dam structure DAM may include a plurality of layers. In an embodiment, the dam structure DAM may include a first layer I1 and a second layer I2. The first layer I1 may be a layer corresponding to the fourth insulating layer 40, and the second layer I2 may be a layer corresponding to the fifth insulating layer 50. That is, the first layer I1 may include the same material as the fourth insulating layer 40, and be formed through the same process as the fourth insulating layer 40. The second layer I2 may include the same material as the fifth insulating layer 50, and be formed through the same process as the fifth insulating layer 50.

The dam structure DAM may be provided in plurality. The plurality of dam structures DAM may be arranged in sequence in a direction that is away from a display area DA.

The dam structure DAM may further include a spacer. The spacer may be disposed on the second layer I2. The spacer may increase a height of the dam structure DAM and prevent the overflow of the organic encapsulation layer OL, and also, when a metal mask is disposed at an upper side of the display panel DP in a follow-up process, the spacer may secure a distance between the metal mask and a lower component and prevent the metal mask from stabbing the lower component.

The display panel DP further includes a conductive pattern CDP disposed in the non-display area NDA, and a dummy pattern DMP adjacent to the conductive pattern CDP. The dummy pattern DMP may be arranged to be spaced further apart from the display area DA than the conductive pattern CDP is. The dummy pattern DMP may be more adjacent to an end DP-S of the display panel DP than the conductive pattern CDP is. An area, in which the conductive pattern CDP and the dummy pattern DMP are disposed, of the non-display area NDA may be described as a bonding area CNA.

The conductive pattern CDP may be one of the plurality of panel signal lines SGL to SGLm, DL1 to DLn, EL1 to ELm, CSL1, CSL2 and PL (see FIG. 5). The conductive pattern CDP may include a conductive metal. The conductive pattern CDP may be disposed on the third insulating layer 30. The third insulating layer 30, which provides a base surface on which the conductive pattern CDP is disposed, may be described as a “lower insulating layer”.

The dummy pattern DMP includes the same material as a portion of the components included in the light emitting element OLED. The dummy pattern DMP may include the same material as a portion of the functional layer FNL and the second electrode CE which are included in the light emitting element OLED. A portion of the dummy pattern DMP may include the same material as the capping layer CPL (see FIG. 6B). The dummy pattern DMP may be disposed on the third insulating layer 30. A base surface of the third insulating layer 30, on which the dummy pattern DMP is disposed, may be disposed below the base surface on which the conductive pattern CDP is disposed.

A distance from an end of the dummy pattern DMP to the end DP-S of the base substrate SUB may be about 3 micrometers to about 100 micrometers. In the display panel DP according to an embodiment, the distance from the end of the dummy pattern DMP to the end DP-S of the base substrate SUB may be set to a smaller distance of about 100 micrometers or less, thereby reducing an unnecessary surface area of the non-display area NDA.

Referring to FIGS. 6A and 6B together, the conductive pattern CDP may include a plurality of layers including conductive metals. The conductive pattern CDP may include a first layer C1, a second layer C2, and a third layer C3 which are stacked in sequence. Each of the first layer C1, the second layer C2, and the third layer C3 may include at least one of, for example, aluminum, platinum, palladium, silver, magnesium, gold, nickel, neodymium, iridium, chromium, lithium, calcium, molybdenum, titanium, tungsten, or copper. The first layer C1 and the third layer C3 may include the same metal. The second layer C2 may include a different metal from the first layer C1 and the third layer C3. For example, the first layer C1 and the third layer C3 may include titanium, and the second layer C2 may include aluminum.

A portion of the components included in the light emitting element OLED may be disposed, in common, in the plurality of pixels, and extend to the non-display area NDA so as to be provided on the conductive pattern CDP. In an embodiment, at least a portion of the functional layer FNL, the second electrode CE, and the capping layer CPL may be disposed in common to be provided on the conductive pattern CDP.

The dummy pattern DMP may include the same material as a portion of the components included in the light emitting element OLED, and, for example, the dummy pattern DMP may include the same material as at least a portion of the functional layer FNL, the second electrode CE, or the capping layer CPL. The dummy pattern DMP may have a multilayer structure including the same material as a portion of the components included in the light emitting element OLED. The dummy pattern DMP may include a first dummy pattern DMP1, a second dummy pattern DMP2, and a third dummy pattern DMP3 which are stacked in sequence. The first dummy pattern DMP1 may include the same material as the functional layer FNL, the second dummy pattern DMP2 may include the same material as the second electrode CE, and the third dummy pattern DMP3 may include the same material as the capping layer CPL. The dummy pattern DMP may be formed through the same process as a portion of the components included in the light emitting element OLED, and include the same material as the portion. The first dummy pattern DMP1 may be formed through the same process as the functional layer FNL, the second dummy pattern DMP2 may be formed through the same process as the second electrode CE, and the third dummy pattern DMP3 may be formed through the same process as the capping layer CPL. The dummy pattern DMP may be disconnected from a portion of the components, included in the light emitting element OLED, by a stepped portion provided by the conductive pattern CDP.

Each of the first inorganic layer IOL1-1 and the second inorganic layer IOL1-2 of the lower inorganic encapsulation layer IOL1 included in the encapsulation layer TFE overlaps the conductive pattern CDP and the dummy pattern DMP. The first inorganic layer IOL1-1 may be disposed on the functional layer FNL, the second electrode CE, and the capping layer CPL, which are provided on the conductive pattern CDP, of the components included in the light emitting element OLED and cover the conductive pattern CDP, the functional layer FNL, the second electrode CE, and the capping layer CPL. The first inorganic layer IOL1-1 may be disposed on the dummy pattern DMP and cover a top surface of the dummy pattern DMP. The first inorganic layer IOL1-1 may be directly disposed on the dummy pattern DMP. Each of the first inorganic layer IOL1-1 and the second inorganic layer IOL1-2 may include at least one of silicon oxide, silicon nitride, silicon oxynitride, titanium oxide, or aluminum oxide. For example, each of the first inorganic layer IOL1-1 and the second inorganic layer IOL1-2 may include one of silicon oxide, silicon nitride, and silicon oxynitride.

The second inorganic layer IOL1-2 may have a portion disposed on the first inorganic layer IOL1-1 and a remaining portion non-overlapping the first inorganic layer IOL1-1. The second inorganic layer IOL1-2 includes a first portion PP1 overlapping the first inorganic layer IOL1-1 and a second portion PP2 non-overlapping the first inorganic layer IOL1-1 and disposed in the non-display area NDA. The second portion PP2 may be a portion extending from the first portion PP1 to the end DP-S of the display panel DP. The second portion PP2 and the first portion PP1 may have a shape of one body and may be portions of the second inorganic layer IOL1-2, which are divided according to an overlapping relationship with the first inorganic layer IOL1-1. The first portion PP1 may be directly disposed on the first inorganic layer IOL1-1.

The first inorganic layer IOL1-1 may include cover portions divided according to an arrangement relationship with the conductive pattern CDP. The first inorganic layer IOL1-1 may include a first cover portion CP1 which is disposed on the conductive pattern CDP, a second cover portion CP2 which covers a side surface of the conductive pattern CDP, and a third cover portion CP3 which is disposed on the dummy pattern DMP. The first cover portion CP1 may be disposed on the functional layer FNL, the second electrode CE, and the capping layer CPL which are disposed on the conductive pattern CDP. The second cover portion CP2 may cover a side surface of each of the first layer C1, the second layer C2, and the third layer C3 of the conductive pattern CDP, and follow a stepped portion generated by the side surfaces of the first layer C1, the second layer C2, and the third layer C3. The third cover portion CP3 may be directly disposed on the dummy pattern DMP. The first cover portion CP1, the second cover portion CP2, and the third cover portion CP3 may be connected and have a shape of one body (i.e., have an integrated shape).

The first portion PP1 of the second inorganic layer IOL1-2 may include sub-portions divided according to an arrangement relationship with the first inorganic layer IOL1-1. The first portion PP1 may include a (1-1)-th portion PP1-1 which is disposed on the first cover portion CP1, a (1-2)-th portion PP1-2 which covers a side surface of the second cover portion CP2, and a (1-3)-th portion PP1-3 which is disposed on the third cover portion CP3. The (1-1)-th portion PP1-1 may be directly disposed on the first cover portion CP1. The (1-2)-th portion PP1-2 may be in contact with the side surface of the second cover portion CP2. The (1-3)-th portion PP1-3 may be directly disposed on the third cover portion CP3. The (1-3)-th portion PP1-3 may extend from above the dummy pattern DMP and be connected to the second portion PP2 so as and have a shape of one body.

Respective ends of the dummy pattern DMP and the first inorganic layer IOL1-1 may define an aligned surface. One end DMP-S provided on the dummy pattern DMP and one end IOL1-1S provided on the third cover portion CP3 of the first inorganic layer IOL1-1 may be parallel to each other and provide the aligned surface. The end of the dummy pattern DMP and the end of the first inorganic layer IOL1-1 may be formed through one etching process and thus provide the aligned surface. The first inorganic layer IOL1-1 may include the end aligned with the dummy pattern DMP through the etching process, and thus not overlap an upper portion of the third insulating layer 30 on which the second portion PP2 is disposed.

The second portion PP2 may not overlap the dummy pattern DMP. The second portion PP2 may be directly disposed on the third insulating layer 30. The second portion PP2 may be in contact with an exposed top surface 30-US of the third insulating layer 30. The exposed top surface 30-US of the third insulating layer 30, on which the second portion PP2 is disposed, may be disposed below the base surface of the third insulating layer 30, on which the dummy pattern DMP is disposed.

The third insulating layer 30 may include at least one of silicon oxide, silicon nitride, silicon oxynitride, titanium oxide, or aluminum oxide. For example, the third insulating layer 30 may include one of silicon oxide, a silicon nitride, and silicon oxynitride. An interface may be provided between the third insulating layer 30 and the second portion PP2. Even when the third insulating layer 30 and the second portion PP2 include the same inorganic material, the third insulating layer 30 and the second portion PP2 may be formed through different processes, thereby providing the interface between the third insulating layer 30 and the second portion PP2.

In the lower inorganic encapsulation layer IOL1, as a portion of the second inorganic layer IOL1-2 does not overlap the first inorganic layer IOL1-1, the lower inorganic encapsulation layer IOL1 may have portions having different thickness. In an embodiment, a sum of a thickness of the first inorganic layer IOL1-1 and a thickness of the first portion PP1 may be greater than a thickness of the second portion PP2. Accordingly, a portion, which overlaps the dummy pattern DMP, of the lower inorganic encapsulation layer IOL1 may be provided with the first inorganic layer IOL1-1 and the first portion PP1 together and thus have a relatively large thickness, and a portion provided with the second portion PP2 non-overlapping the dummy pattern DMP may have a relatively small thickness.

The display panel DP included in the electronic device according to an embodiment may include the conductive pattern CDP and the dummy pattern DMP disposed in the non-display area NDA, the lower inorganic encapsulation layer IOL1 of the encapsulation layer TFE may include the first inorganic layer IOL1-1 and the second inorganic layer IOL1-2, and the second inorganic layer IOL1-2 may have the portion disposed on the first inorganic layer IOL1-1, and the remaining portion having a shape non-overlapping the first inorganic layer IOL1-1, thereby reducing the unnecessary surface area or undesired surface area of the non-display area NDA. In the display panel DP according to an embodiment, the second inorganic layer IOL1-2 may include the first portion PP1 overlapping the first inorganic layer IOL1-1, and the second portion PP2 non-overlapping the first inorganic layer IOL1-1 and disposed in the non-display area NDA, and the first inorganic layer IOL1-1 may have the one surface aligned with the dummy pattern DMP. In the display panel DP according to an embodiment, the respective ends of the first inorganic layer IOL1-1 and the dummy pattern DMP may be aligned through the etching process to include the aligned surface, thereby decreasing a width of an area in which the dummy pattern DMP is disposed. Accordingly, the unnecessary surface area of the non-display area NDA may be reduced. In some aspects, the second portion PP2 of the second inorganic layer IOL1-2 may be in contact with the exposed top surface 30-US of the third insulating layer 30, thereby achieving a robust bonding structure by a contact between an inorganic layer and an inorganic layer. Accordingly, the durability of the display panel DP and the electronic device including the display panel DP may be improved.

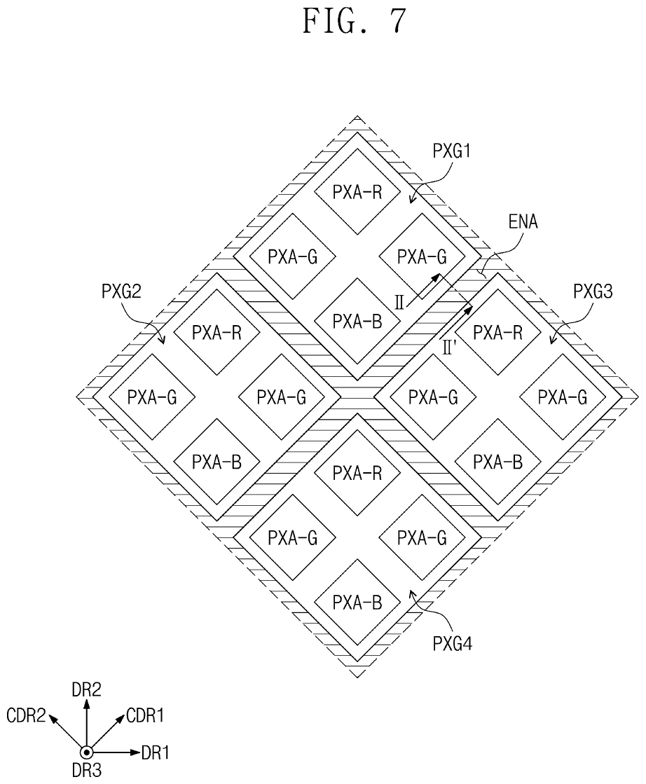

FIG. 7 is a plan view of pixel units according to an embodiment of the inventive concept. As an example, FIG. 7 illustrates a planar arrangement of some pixels of a plurality of pixels PX included in the display area DA (see FIG. 5).

Referring to FIG. 7, in this embodiment, one pixel unit PXG may include the pixels described with reference to FIGS. 4A and 4B. The pixel unit PXG may be provided in plurality, and the plurality of pixel units PXG may be arranged along the first and second directions DR1 and DR2 within the display area DA described with reference to FIG. 5. As an example, FIG. 7 illustrates four pixel units including a first pixel unit PXG1, a second pixel unit PXG2, a third pixel unit PXG3, and a fourth pixel unit PXG4.

Each of the pixel units PXG according to an embodiment may include first to third emission areas PXA-R, PXA-G and PXA-B. The first emission area PXA-R may provide red light. The second emission area PXA-B may provide blue light. The third emission area PXA-G may provide green light. One pixel unit PXG may include two third emission areas PXA-G, one first emission area PXA-R, and one second emission area PXA-B. The first emission area PXA-R, the second emission area PXA-B, and the third emission areas PXA-G may be spaced apart from each other along a first diagonal direction CDR1, which is a direction between the first direction DR1 and the second direction DR2, and a second diagonal directions CDR2 perpendicular to the first diagonal direction CDR1.

In this embodiment, the first emission area PXA-R, the second emission area PXA-B, and the third emission areas PXA-G may each have a rhombus shape but are not limited thereto. The first emission area PXA-R, the second emission area PXA-B, and the third emission areas PXA-G may each have various shapes. For example, the first emission area PXA-R, the second emission area PXA-B, and the third emission areas PXA-G may each have a rectangular shape or have a rectangular shape having round corners.

An area between the first emission area PXA-R, the second emission area PXA-B, and the third emission areas PXA-G may be defined as a non-emission area NPXA.

In an embodiment, an area between neighboring pixel units PXG within the non-emission area NPXA may be defined as an encapsulation area ENA. The encapsulation area ENA may be defined as an area in which insulating layers including inorganic materials are in contact with each other. According to this embodiment, the encapsulation area ENA may surround each of the pixel units PXG. Accordingly, the pixel units PXG may be individually encapsulated. Thus, a path through which moisture/oxygen is introduced into each of the pixel units PXG may be blocked by the encapsulation area ENA.

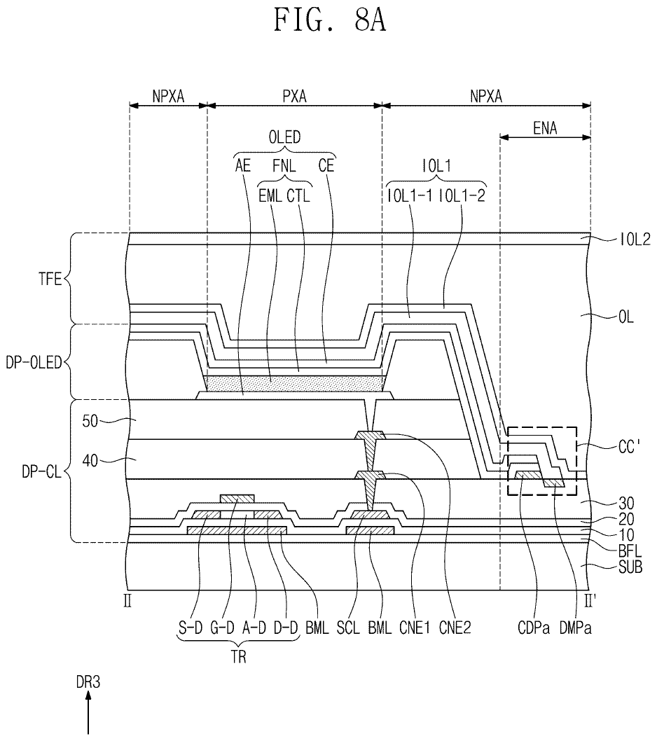

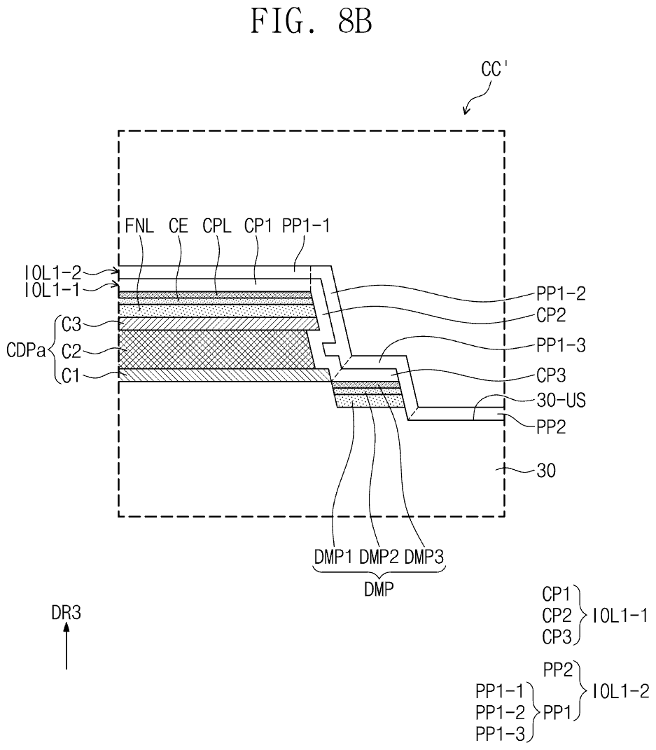

FIG. 8A is a cross-sectional view of a portion of a display panel according to an embodiment of the inventive concept. FIG. 8B is an enlarged cross-sectional view of a portion of a display panel according to an embodiment of the inventive concept. FIG. 8A illustrates a cross-section taken along line II-II′ illustrated in FIG. 7. FIG. 8B is an enlarged cross-sectional view of area CC′ illustrated in FIG. 8A.

Referring to FIG. 8A, a display panel DP may include a base substrate SUB and a plurality of insulating layers 10, 20, 30, 40 and 50 disposed on the base substrate SUB. As an example, FIG. 8A illustrates some components of one pixel PX. The pixel PX may include a transistor TR and a light emitting element OLED.

A shielding electrode BML may be disposed on a buffer layer BFL. The shielding electrode BML may overlap the transistor TR. In an embodiment, the shielding electrode BML may be also disposed below a signal transmission area SCL. The shielding electrode BML may block light incident on the transistor TR or the signal transmission area SCL from below the display panel DP, and protect semiconductor patterns or conductive patterns such as, for example, the transistor TR and the signal transmission area SCL. The shielding electrode BML may include a conductive material. In an example in which a voltage is applied to the shielding electrode BML, a threshold voltage of the transistor TR disposed on the shielding electrode BML may be maintained. However, the shielding electrode BML is not limited thereto and may be a floating electrode. In an embodiment, the shielding electrode BML may be omitted.

The transistor TR may be electrically connected to the light emitting element OLED. A source S-D, an active A-D, and a drain D-D of the transistor TR may be provided from the semiconductor pattern. FIG. 8A illustrates a portion of the signal transmission area SCL provided from the semiconductor pattern. The signal transmission area SCL may be disposed on a first insulating layer 10. Although not separately illustrated, the signal transmission area SCL may be connected to the drain D-D of the transistor TR on a plane. A second insulating layer 20 may cover the source S-D, the active A-D, and the drain D-D of the transistor TR and the signal transmission area SCL, which are disposed on the first insulating layer 10.

A first connection electrode CNE1 may be disposed on a third insulating layer 30, and a second connection electrode CNE2 may be disposed on a fourth insulating layer 40. The first connection electrode CNE1 may pass through the second insulating layer 20 and the third insulating layer 30 and be connected to the signal transmission area SCL. The second connection electrode CNE2 may pass through the fourth insulating layer 40 and be electrically connected to the first connection electrode CNE1.

However, at least one of the first connection electrode CNE1 and the second connection electrode CNE2 may be omitted. Alternatively, an additional connection electrode which connects the light emitting element OLED to the signal transmission area SCL may be further disposed. A method for an electrical connection between the light emitting element OLED and the transistor TR may be variously changed according to the number of the insulating layers disposed between the light emitting element OLED and the transistor TR, and is not limited to any one embodiment.

A fifth insulating layer 50 may be disposed on the fourth insulating layer 40 and cover the second connection electrode CNE2.

The light emitting element OLED may be disposed on the fifth insulating layer 50. The light emitting element OLED may include a first electrode AE, a functional layer FNL, and a second electrode CE. The first electrode AE may be electrically connected to the transistor TR through the first connection electrode CNE1 and the second connection electrode CNE2. The first electrode AE may be, for example, an anode.

A pixel definition layer PDL is disposed on the fifth insulating layer 50 and exposes at least a portion of the first electrode AE. The pixel definition layer PDL may be an inorganic layer, an organic layer, or a combination thereof, and may have a single-layer or multilayer structure. As used herein, the pixel definition layer PDL and the light emitting element OLED correspond to the light emitting element layer DP-OLED described herein. The pixel definition layer PDL may include an opening which exposes a portion of the first electrode AE, and an emission area PXA may be defined by the opening of the pixel definition layer PDL.

The functional layer FNL may be disposed on the first electrode AE. The functional layer FNL may include at least an emission layer EML. The emission layer EML may provide light of a certain color. In this embodiment, the emission layer EML patterned in the emission area PXA and having a single-layer structure is illustrated as an example, but embodiments of the present disclosure are not limited thereto. For example, the emission layer EML may have a multilayer structure. In some aspects, the emission layer EML may extend toward a top surface of the pixel definition layer PDL and be provided, in common, to a plurality of pixels. The second electrode CE may be disposed on the emission layer EML. The second electrode CE may be, for example, a cathode.

The functional layer FNL may further include a charge control layer CTL. The charge control layer CTL may be disposed between the first electrode AE and the second electrode CE. As an example, FIG. 8A illustrates the charge control layer CTL which is disposed between the second electrode CE and the emission layer EML, but the charge control layer CTL is not limited thereto and may be provided between the first electrode AE and the emission layer EML. The charge control layer CTL may include an electron control layer (or an electron control region) may be disposed between the second electrode CE and the emission layer EML, and a hole control layer (or a hole control region) disposed between the first electrode AE and the emission layer EML. The charge control layer CTL may be provided, in common, to the plurality of pixels.

The light emitting element OLED may further include a capping layer CPL (see FIG. 8B) disposed on the second electrode CE. The capping layer CPL may be provided to protect a component disposed below the capping layer CPL and improve optical properties of the light emitting element OLED. The capping layer CPL may have a refractive index of about 1.6 or less in a visible wavelength range.

An encapsulation layer TFE is disposed on the pixel definition layer PDL and covers the light emitting element OLED. The encapsulation layer TFE includes at least an inorganic layer. The encapsulation layer TFE may include a plurality of inorganic encapsulation layers, and at least one organic encapsulation layer disposed between the plurality of inorganic encapsulation layers. In an embodiment, the encapsulation layer TFE may include a lower inorganic encapsulation layer IOL1, an organic encapsulation layer OL, and an upper inorganic encapsulation layer IOL2. The lower inorganic encapsulation layer IOL1 may be disposed on the second electrode CE.

The lower inorganic encapsulation layer IOL1 may be disposed on the second electrode CE. The organic encapsulation layer OL may be disposed on the lower inorganic encapsulation layer IOL1. The upper inorganic encapsulation layer IOL2 may be disposed on the organic encapsulation layer OL and cover the organic encapsulation layer OL. The lower inorganic encapsulation layer IOL1 and the upper inorganic encapsulation layer IOL2 may each include a silicon nitride layer, a silicon oxynitride layer, a silicon oxide layer, a titanium oxide layer, an aluminum oxide layer, or the like, but are not particularly limited thereto. The organic encapsulation layer OL may include an acrylic organic layer or a silicon-based layer, and is not particularly limited. The lower inorganic encapsulation layer IOL1 and the upper inorganic encapsulation layer IOL2 may protect the light emitting element OLED from moisture/oxygen or foreign matter.

The lower inorganic encapsulation layer IOL1 includes a plurality of inorganic layers. The lower inorganic encapsulation layer IOL1 includes a first inorganic layer IOL1-1 which is disposed on the second electrode CE and covers the light emitting element OLED, and a second inorganic layer IOL1-2 which is disposed on the first inorganic layer IOL1-1. The second inorganic layer IOL1-2 may be directly disposed on the first inorganic layer IOL1-1, and the organic encapsulation layer OL may be directly disposed on the second inorganic layer IOL1-2.

The display panel DP further includes a conductive pattern CDPa disposed in a non-emission area NPXA, and a dummy pattern DMPa adjacent to the conductive pattern CDPa. The dummy pattern DMPa may be arranged to be spaced further apart from the emission area PXA compared to the conductive pattern CDPa. The dummy pattern DMPa may be more adjacent to an end DP-S of the display panel DP compared to the conductive pattern CDPa. An area, in which the conductive pattern CDPa and the dummy pattern DMPa are disposed, of the non-emission area NPXA may be described as an encapsulation area ENA.

The conductive pattern CDPa may be one of the plurality of panel signal lines SGL to SGLm, DL1 to DLn, EL1 to ELm, CSL1, CSL2 and PL (see FIG. 5). The conductive pattern CDPa may include a conductive metal. The conductive pattern CDPa may include a conductive metal. The third insulating layer 30, which provides a base surface on which the conductive pattern CDPa is disposed, may be described as a “lower insulating layer”.

The dummy pattern DMPa includes the same material as a portion of the components included in the light emitting element OLED. The dummy pattern DMPa may include the same material as a portion of the functional layer FNL and the second electrode CE which are included in the light emitting element OLED. A portion of the dummy pattern DMPa may include the same material as the capping layer CPL (see FIG. 8B). The dummy pattern DMPa may be disposed on the third insulating layer 30. A base surface of the third insulating layer 30, on which the dummy pattern DMPa is disposed, may be disposed below the base surface on which the conductive pattern CDPa is disposed.

Referring to FIGS. 8A and 8B together, the conductive pattern CDPa may include a plurality of layers including conductive metals. The conductive pattern CDPa may include a first layer C1, a second layer C2, and a third layer C3 which are stacked in sequence. Each of the first layer C1, the second layer C2, and the third layer C3 may include at least one of, for example, aluminum, platinum, palladium, silver, magnesium, gold, nickel, neodymium, iridium, chromium, lithium, calcium, molybdenum, titanium, tungsten, or copper. The first layer C1 and the third layer C3 may include the same metal. The second layer C2 may include a different metal from the first layer C1 and the third layer C3. For example, the first layer C1 and the third layer C3 may include titanium, and the second layer C2 may include aluminum.

A portion of the components included in the light emitting element OLED may be disposed, in common, in the plurality of pixels, and extend to the non-emission area NPXA so as to be provided on the conductive pattern CDPa. In an embodiment, at least a portion of the functional layer FNL, the second electrode CE, and the capping layer CPL may be disposed in common to be provided on the conductive pattern CDPa.

The dummy pattern DMPa may include the same material as a portion of the components included in the light emitting element OLED, and, for example, the dummy pattern DMPa may include the same material as at least a portion of the functional layer FNL, the second electrode CE, and the capping layer CPL. The dummy pattern DMPa may have a multilayer structure including the same material as a portion of the components included in the light emitting element OLED. The dummy pattern DMPa may include a first dummy pattern DMP1, a second dummy pattern DMP2, and a third dummy pattern DMP3 which are stacked in sequence. The first dummy pattern DMP1 may include the same material as the functional layer FNL, the second dummy pattern DMP2 may include the same material as the second electrode CE, and the third dummy pattern DMP3 may include the same material as the capping layer CPL. The dummy pattern DMPa may be formed through the same process as a portion of the components included in the light emitting element OLED, and include the same material as the portion. The first dummy pattern DMP1 may be formed through the same process as the functional layer FNL, the second dummy pattern DMP2 may be formed through the same process as the second electrode CE, and the third dummy pattern DMP3 may be formed through the same process as the capping layer CPL. The dummy pattern DMPa may be disconnected from a portion of the components, included in the light emitting element OLED, by a stepped portion provided by the conductive pattern CDPa.

Each of the first inorganic layer IOL1-1 and the second inorganic layer IOL1-2 of the lower inorganic encapsulation layer IOL1 included in the encapsulation layer TFE, overlaps the conductive pattern CDPa and the dummy pattern DMPa. The first inorganic layer IOL1-1 may be disposed on the functional layer FNL, the second electrode CE, and the capping layer CPL, which are provided on the conductive pattern CDPa, of the components included in the light emitting element OLED and cover the conductive pattern CDPa, the functional layer FNL, the second electrode CE, and the capping layer CPL. The first inorganic layer IOL1-1 may be disposed on the dummy pattern DMPa and cover a top surface of the dummy pattern DMPa. The first inorganic layer IOL1-1 may be directly disposed on the dummy pattern DMPa. Each of the first inorganic layer IOL1-1 and the second inorganic layer IOL1-2 may include at least one of silicon oxide, silicon nitride, silicon oxynitride, titanium oxide, or aluminum oxide. For example, each of the first inorganic layer IOL1-1 and the second inorganic layer IOL1-2 may include one of silicon oxide, silicon nitride, and silicon oxynitride.

The second inorganic layer IOL1-2 may have a portion disposed on the first inorganic layer IOL1-1, and a remaining portion non-overlapping the first inorganic layer IOL1-1. The second inorganic layer IOL1-2 includes a first portion PP1 overlapping the first inorganic layer IOL1-1, and a second portion PP2 non-overlapping the first inorganic layer IOL1-1 and disposed in the non-display area NDA. The second portion PP2 and the first portion PP1 may have a shape of one body, and be portions of the second inorganic layer IOL1-2, which are divided according to an overlapping relationship with the first inorganic layer IOL1-1. The first portion PP1 may be directly disposed on the first inorganic layer IOL1-1.

The first inorganic layer IOL1-1 may include cover portions divided according to an arrangement relationship with the conductive pattern CDPa. The first inorganic layer IOL1-1 may include a first cover portion CP1 which is disposed on the conductive pattern CDPa, a second cover portion CP2 which covers a side surface of conductive pattern CDPa, and a third cover portion CP3 which is disposed on the dummy pattern DMPa. The first cover portion CP1 may be disposed on the functional layer FNL, the second electrode CE, and the capping layer CPL which are disposed on the conductive pattern CDPa. The second cover portion CP2 may cover a side surface of each of the first layer C1, the second layer C2, and the third layer C3 of the conductive pattern CDPa, and follows a stepped portion generated by the side surfaces of the first layer C1, the second layer C2, and the third layer C3. The third cover portion CP3 may be directly disposed on the dummy pattern DMPa. The first cover portion CP1, the second cover portion CP2, and the third cover portion CP3 may be connected and have a shape of one body.

The first portion PP1 of the second inorganic layer IOL1-2 may include sub-portions divided according to an arrangement relationship with the first inorganic layer IOL1-1. The first portion PP1 may include a (1-1)-th portion PP1-1 which is disposed on the first cover portion CP1, a (1-2)-th portion PP1-2 which covers a side surface of the second cover portion CP2, and a (1-3)-th portion PP1-3 which is disposed on the third cover portion CP3. The (1-1)-th portion PP1-1 may be directly disposed on the first cover portion CP1. The (1-2)-th portion PP1-2 may be in contact with the side surface of the second cover portion CP2. The (1-3)-th portion PP1-3 may be directly disposed on the third cover portion CP3. The (1-3)-th portion PP1-3 may extend from above the dummy pattern DMPa and be connected to the second portion PP2 so as and have a shape of one body.

Respective ends of the dummy pattern DMPa and the first inorganic layer IOL1-1 may define an aligned surface. One end DMP-S provided on the dummy pattern DMPa and one end IOL1-1S provided on the third cover portion CP3 of the first inorganic layer IOL1-1 may be parallel to each other to provide the aligned surface. The end of the dummy pattern DMPa and the end of the first inorganic layer IOL1-1 may be formed through one etching process and thus provide the aligned surface. The first inorganic layer IOL1-1 may include the end aligned with the dummy pattern DMPa through the etching process, and thus not overlap an upper portion of the third insulating layer 30 on which the second portion PP2 is disposed.

The second portion PP2 may not overlap the dummy pattern DMPa. The second portion PP2 may be directly disposed on the third insulating layer 30. The second portion PP2 may be in contact with an exposed top surface 30-US of the third insulating layer 30. The exposed top surface 30-US of the third insulating layer 30, on which the second portion PP2 is disposed, may be disposed below the base surface of the third insulating layer 30, on which the dummy pattern DMPa is disposed.

The third insulating layer 30 may include at least one of silicon oxide, silicon nitride, silicon oxynitride, titanium oxide, or aluminum oxide. For example, the third insulating layer 30 may include one of silicon oxide, silicon nitride, or silicon oxynitride. An interface may be provided between the third insulating layer 30 and the second portion PP2. Even when the third insulating layer 30 and the second portion PP2 include the same inorganic material, the third insulating layer 30 and the second portion PP2 may be formed through different processes, thereby providing the interface between the third insulating layer 30 and the second portion PP2.

In the lower inorganic encapsulation layer IOL1, as a portion of the second inorganic layer IOL1-2 does not overlap the first inorganic layer IOL1-1, the lower inorganic encapsulation layer IOL1 may have portions having different thickness. In an embodiment, a sum of a thickness of the first inorganic layer IOL1-1 and a thickness of the first portion PP1 may be greater than a thickness of the second portion PP2. Accordingly, a portion, which overlaps the dummy pattern DMPa, of the lower inorganic encapsulation layer IOL1 may be provided with the first inorganic layer IOL1-1 and the first portion PP1 together and thus have a large thickness, and a portion provided with the second portion PP2 non-overlapping the dummy pattern DMPa may have a relatively small thickness.

The display panel DP included in the electronic device according to an embodiment may include the conductive pattern CDPa and the dummy pattern DMPa disposed in the encapsulation area ENA of the non-emission area NPXA, and also, the lower inorganic encapsulation layer IOL1 of the encapsulation layer TFE may include the first inorganic layer IOL1-1 and the second inorganic layer IOL1-2, and the second inorganic layer IOL1-2 may have the portion disposed on the first inorganic layer IOL1-1, and the remaining portion having a shape non-overlapping the first inorganic layer IOL1-1, thereby having a structure in which the pixel units PXG (see FIG. 7) are individually encapsulated.

Hereinafter, a method for manufacturing an electronic device according to an embodiment of the inventive concept will be described with reference to the accompanying drawings.

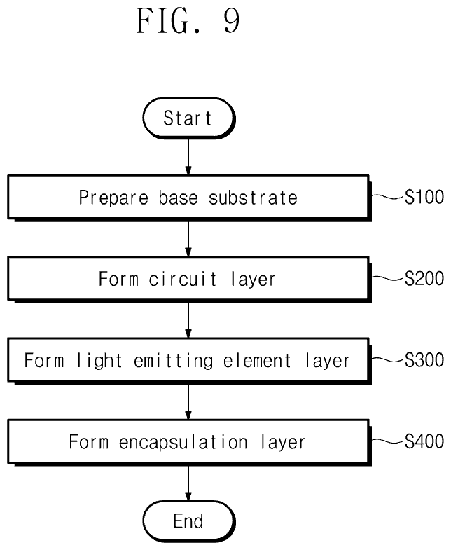

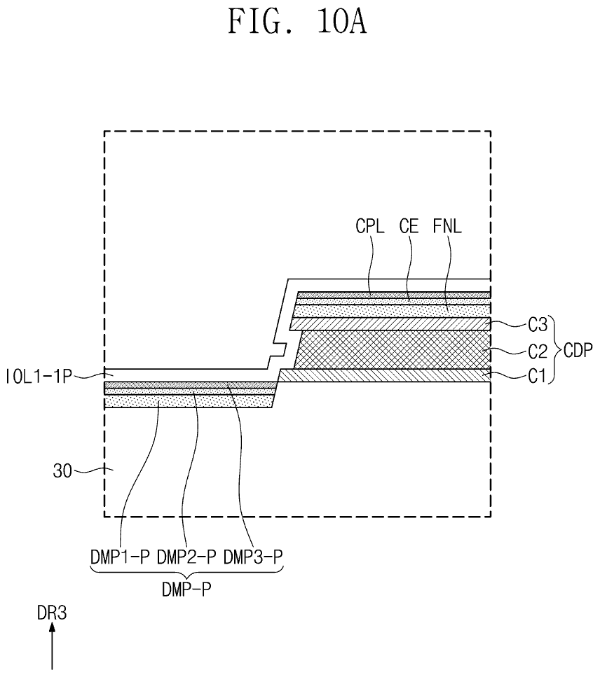

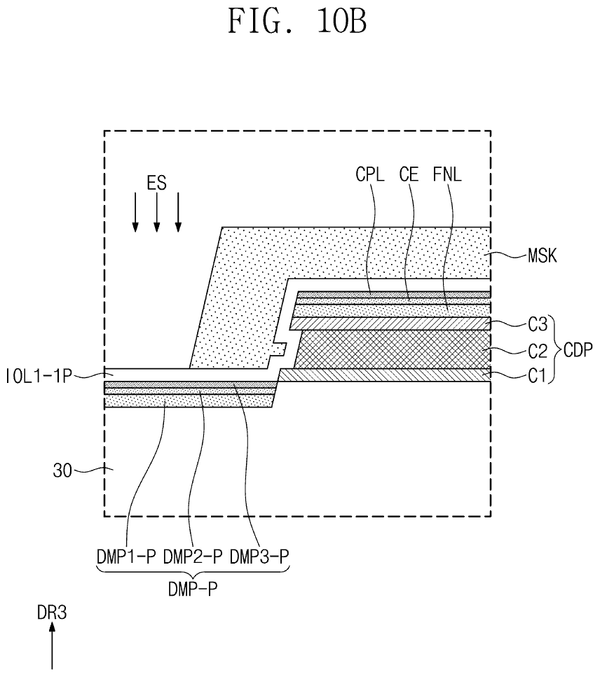

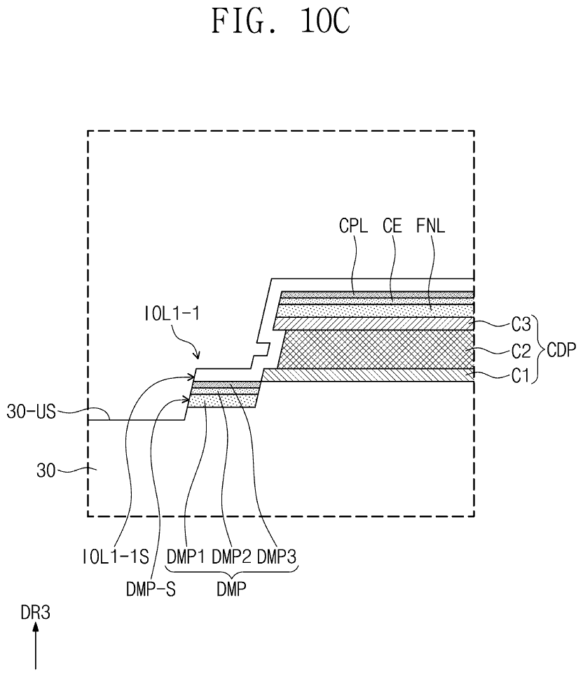

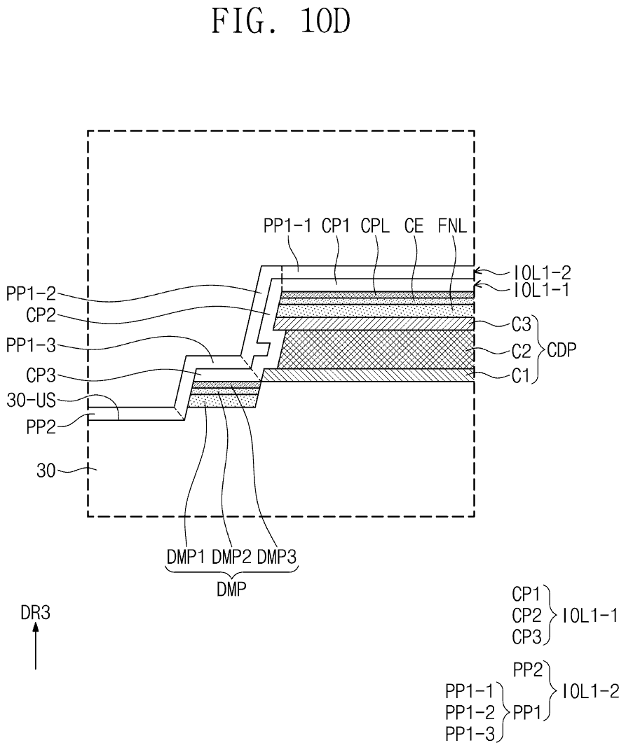

FIG. 9 is a flowchart of a method for manufacturing an electronic device according to an embodiment of the inventive concept. FIGS. 10A to 10D are enlarged cross-sectional views illustrating some steps of a method for manufacturing an electronic device according to an embodiment of the inventive concept. In a cross-section corresponding to FIG. 6B, FIGS. 10A to 10D illustrate one states in some steps of the method for manufacturing the electronic device.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIG. 9, the method for manufacturing the electronic device according to an embodiment includes preparing a base substrate including a display area and a non-display area adjacent to the display area (S100), forming a circuit layer on the base substrate (S200), forming, on the circuit layer, a light emitting element layer including a light emitting element (S300), and forming an encapsulation layer on the light emitting element layer (S400).

As described with reference to FIG. 6A and the like, a light emitting element OLED includes a first electrode AE disposed on a circuit layer DP-CL, a functional layer FNL disposed on the first electrode AE and including at least an emission layer EML, and a second electrode CE disposed on the functional layer FNL. The circuit layer DP-CL includes a lower insulating layer 30, a conductive pattern CDP overlapping a non-display area NDA and disposed on the lower insulating layer 30, and a dummy pattern DMP disposed on the lower insulating layer 30 and spaced further apart from a display area DA than the conductive pattern CDP is. The dummy pattern DMP includes the same material as at least a portion of the functional layer FNL and the second electrode CE.

Referring to FIGS. 6A and 10A together, the forming of the encapsulation layer (S400) includes forming a preliminary first inorganic layer IOL1-1P which covers the conductive pattern CDP and a dummy pattern DMP-P. In the forming of the preliminary first inorganic layer IOL1-1P, the dummy pattern DMP-P is in a state before an etching process and may have a larger width than the dummy pattern DMP which results from the etching, illustrated in FIG. 6A. As used herein, the dummy pattern DMP-P in the state before the etching process may be described as a “preliminary dummy pattern”, and the dummy pattern DMP-P may extend to an end DP-S of a display panel DP.

The dummy pattern DMP-P may be formed through the same process as the component included in the light emitting element OLED. The dummy pattern DMP-P may include a first dummy pattern DMP1, a second dummy pattern DMP2, and a third dummy pattern DMP3 which are stacked in sequence. The first dummy pattern DMP1 may be formed through the same process as the functional layer FNL, the second dummy pattern DMP2 may be formed through the same process as the second electrode CE, and the third dummy pattern DMP3 may be formed through the same process as the capping layer CPL. In a process of depositing, as a common layer, each of the functional layer FNL, the second electrode CE, and the capping layer CPL included in the light emitting element OLED, the dummy pattern DMP-P may be disconnected by a stepped portion formed by the conductive pattern CDP. A base surface of the third insulating layer 30, on which the dummy pattern DMP-P is formed, may be disposed below a base surface on which the conductive pattern CDP is disposed.

The preliminary first inorganic layer IOL1-1P may be formed such that the preliminary first inorganic layer IOL1-1P covers all the conductive pattern CDP, the capping layer CPL, and the dummy pattern DMP-P. The preliminary first inorganic layer IOL1-1P may include at least one of silicon oxide, silicon nitride, silicon oxynitride, titanium oxide, or aluminum oxide.

Referring to FIGS. 6A and 10A to 10C together, the forming of the encapsulation layer (S400) includes etching a portion of the preliminary first inorganic layer IOL1-1P to form a first inorganic layer IOL1-1.

The etching of the portion of the preliminary first inorganic layer IOL1-1P may be performed by forming a mask MSK and then providing an etchant material ES. The mask MSK may include a transparent conductive material. The mask MSK may include an opening corresponding to a portion, which overlaps the dummy pattern DMP-P, of the preliminary first inorganic layer IOL1-1P, and the etchant material ES may be provided to the opening included in the mask MSK. The etchant material ES may be an etchant gas or an etchant solution. The mask MSK may be removed after the etching process.

The first inorganic layer IOL1-1 is formed after the etching process. In the forming of the first inorganic layer IOL1-1, a portion of the dummy pattern DMP-P may be etched together. After the etching process, respective ends of the dummy pattern DMP and the first inorganic layer IOL1-1 may define an aligned surface. One end DMP-S provided on the dummy pattern DMP and one end IOL1-1S provided on a third cover portion CP3 of the first inorganic layer IOL1-1 may be parallel to each other and provide the aligned surface. The end of the dummy pattern DMP and the end of the first inorganic layer IOL1-1 may be formed through one etching process and thus provide the aligned surface.

In the forming of the first inorganic layer IOL1-1, a portion of a top surface 30-U of the lower insulating layer 30 is exposed. The exposed top surface 30-U of the lower insulating layer 30 may be disposed below the base surface of the lower insulating layer 30 on which the dummy pattern DMP is disposed.

Referring to FIGS. 6A, 10C, and 10D together, the forming of the encapsulation layer (S400) includes forming a second inorganic layer IOL1-2 on the first inorganic layer IOL1-1.

The second inorganic layer IOL1-2 may cover the top surface of the first inorganic layer IOL1-1, and the second inorganic layer IOL1-2 may also be formed on the exposed top surface 30-U of the lower insulating layer 30. The second inorganic layer IOL1-2 includes a first portion PP1 overlapping the first inorganic layer IOL1-1, and a second portion PP2 non-overlapping the first inorganic layer IOL1-1. The second inorganic layer IOL1-2 may be formed such that the second inorganic layer IOL1-2 is in contact with the exposed top surface 30-U of the lower insulating layer 30.

The method for manufacturing the electronic device according to an embodiment may include a process of forming the first inorganic layer IOL1-1 through the etching process, and an unnecessary portion or undesired portion of the dummy pattern DMP-P may be removed during the etching process, thereby reducing a width of an area in which the dummy pattern DMP is disposed. Accordingly, an unnecessary surface area or undesired surface area of a non-display area NDA of the electronic device may be reduced. In some aspects, the second portion PP2 of the second inorganic layer IOL1-2 may be formed such that the second portion PP2 is in contact with the exposed top surface 30-US of the third insulating layer 30, thereby achieving a robust bonding structure by a contact between an inorganic layer and an inorganic layer. Accordingly, durability of the electronic device may be improved.

The electronic device according to the embodiment may reduce the large area occupied by the dummy pattern through the etching process, thereby reducing the unnecessary surface area or undesired area of the non-display area. Moreover, the additional inorganic layer may be provided to the lower inorganic encapsulation layer, thereby achieving the robust bonding structure by the contact between the inorganic layer and the inorganic layer. Accordingly, the durability of the electronic device may be improved.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims to be described later. Therefore, the technical scope of the inventive concept is not to be limited to the contents stated in the detailed description of the specification, but should be determined by the claims.

What is claimed is:

1. An electronic device comprising:
a base substrate comprising a display area and a non-display area adjacent to the display area;
a circuit layer on the base substrate;
a light emitting element layer on the circuit layer and comprising a light emitting element; and
an encapsulation layer which covers the light emitting element,
wherein:
the light emitting element comprises:
a first electrode on the circuit layer;
a functional layer on the first electrode and comprising at least an emission layer; and
a second electrode on the functional layer,
the circuit layer comprises:
a conductive pattern which is on the non-display area; and
a dummy pattern which is spaced further apart from the display area compared to the conductive pattern,
the dummy pattern comprises a same material as at least a portion of the functional layer or the second electrode,
the encapsulation layer comprises:
a first inorganic layer which covers the light emitting element and the dummy pattern; and
a second inorganic layer, wherein a portion of the second inorganic layer is on the first inorganic layer, and
the second inorganic layer comprises a first portion overlapping the first inorganic layer, and a second portion non-overlapping the first inorganic layer and located in the non-display area.

2. The electronic device of claim 1, wherein the second portion does not overlap the dummy pattern.

3. The electronic device of claim 1, wherein the second inorganic layer comprises at least one of silicon oxide, silicon nitride, silicon oxynitride, titanium oxide, or aluminum oxide.

4. The electronic device of claim 1, wherein a distance from an end of the dummy pattern to an end of the base substrate is about 3 micrometers to about 100 micrometers.

5. The electronic device of claim 1, wherein:
the conductive pattern comprises a first layer, a second layer, and a third layer which are stacked in sequence,
the first layer and the third layer comprise a same metal, and
the second layer comprises a different metal from each of the first layer and the third layer.

6. The electronic device of claim 1, wherein the first inorganic layer comprises:
a first cover portion on the conductive pattern;
a second cover portion which covers a side surface of conductive pattern; and
a third cover portion which covers an upper portion of the dummy pattern.

7. The electronic device of claim 6, wherein the first portion of the second inorganic layer comprises:
a (1-1)-th portion on the first cover portion;
a (1-2)-th portion which covers a side surface of the second cover portion; and
a (1-3)-th portion on the third cover portion,
wherein the (1-3)-th portion and the second portion are connected and have a shape of one body.

8. The electronic device of claim 1, wherein the dummy pattern comprises:
a first dummy pattern comprising a same material as at least the portion of the functional layer; and
a second dummy pattern on the first dummy pattern and comprising a same material as the second electrode.

9. The electronic device of claim 1, wherein a sum of a thickness of the first inorganic layer and a thickness of the first portion is greater than a thickness of the second portion.

10. The electronic device of claim 1, wherein the first portion of the second inorganic layer is directly on the first inorganic layer.

11. The electronic device of claim 1, wherein the encapsulation layer further comprises:
an organic encapsulation layer on the first portion of the second inorganic layer; and
an upper inorganic encapsulation layer on the organic encapsulation layer.

12. The electronic device of claim 1, wherein:
the circuit layer further comprises a lower insulating layer configured to provide a base surface on which the conductive pattern is disposed, and
the second portion is in contact with a top surface of the lower insulating layer.

13. The electronic device of claim 12, wherein:
the lower insulating layer comprises at least one of silicon oxide, silicon nitride, silicon oxynitride, titanium oxide, or aluminum oxide, and
an interface is provided between the second portion and the lower insulating layer.

14. The electronic device of claim 1, wherein:
the light emitting element further comprises a capping layer on the second electrode, and
the dummy pattern comprises:
a first dummy pattern comprising a same material as at least the portion of the functional layer;
a second dummy pattern on the first dummy pattern and comprising a same material as the second electrode; and
a third dummy pattern on the second dummy pattern and comprising a same material as the capping layer.

15. The electronic device of claim 1, wherein an end of the dummy pattern and an end of the first inorganic layer define an aligned surface.

16. An electronic device comprising:
a base substrate comprising a first area and a second area adjacent to the first area;
a circuit layer on the base substrate;
a light emitting element layer on the circuit layer and comprising a light emitting element; and
an encapsulation layer which covers the light emitting element,
wherein:
the light emitting element comprises:
a first electrode on the circuit layer;
a functional layer on the first electrode and comprising at least an emission layer; and
a second electrode on the functional layer,
the circuit layer comprises:
a conductive pattern in the first area; and
a dummy pattern in the second area and spaced apart from the first area, with the conductive pattern between the dummy pattern and the first area,
the dummy pattern comprises a same material as at least a portion of the functional layer or the second electrode,
the encapsulation layer comprises a lower inorganic encapsulation layer, wherein a portion of the lower inorganic encapsulation layer covers the light emitting element and the dummy pattern, and
wherein a thickness of a portion, which overlaps the dummy pattern, of the lower inorganic encapsulation layer is greater than a thickness of a portion non-overlapping the dummy pattern and in the second area.

17. A method for manufacturing an electronic device, the method comprising:
preparing a base substrate comprising a display area and a non-display area adjacent to the display area;
forming a circuit layer on the base substrate;
forming, on the circuit layer, a light emitting element layer comprising a light emitting element; and
forming an encapsulation layer on the light emitting element layer,
wherein the light emitting element comprises:
a first electrode on the circuit layer;
a functional layer on the first electrode and comprising at least an emission layer; and
a second electrode on the functional layer,
the circuit layer comprises:
a lower insulating layer;
a conductive pattern overlapping the non-display area and on the lower insulating layer; and
a dummy pattern which is on the lower insulating layer and is spaced further apart from the display area compared to the conductive pattern,
the dummy pattern comprises a same material as at least a portion of the functional layer or the second electrode,
the forming of the encapsulation layer comprises:
forming a preliminary first inorganic layer which covers the conductive pattern and the dummy pattern;
etching a portion of the preliminary first inorganic layer, wherein etching the portion of the preliminary first inorganic layer forms a first inorganic layer; and
forming a second inorganic layer on the first inorganic layer,
wherein, in the etching of the portion of the preliminary first inorganic layer, a portion of a top surface of the lower insulating layer is exposed, and the second inorganic layer is in contact with the exposed portion of the top surface of the lower insulating layer.

18. The method of claim 17, wherein, in the etching of the portion of the preliminary first inorganic layer, a portion of the dummy pattern is etched together.

19. The method of claim 17, wherein the second inorganic layer comprises:
a first portion in contact with a top surface of the first inorganic layer, and
a second portion in contact with the exposed portion of the top surface of the lower insulating layer.

20. The method of claim 17, wherein an end of the first inorganic layer and an end of the dummy pattern are aligned with each other after the etching of the portion of the preliminary first inorganic layer.
